(19) United States
(12) Patent Application Publication
(10) Pub. No.: US 2025/0346767 A1
(43) Pub. Date: Nov. 13, 2025

(54) TIN PRECURSORS FOR DEPOSITION OF EUV DRY RESIST

(71) Applicant: Lam Research Corporation, Fremont, CA (US)

(72) Inventors: Raymond Nicholas VRTIS, Carlsbad, CA (US); Timothy William WEIDMAN, Sunnyvale, CA (US); Jason Philip COYLE, San Jose, CA (US); Qinghuang LIN, Yorktown Heights, NY (US); Chenghao WU, San Jose, CA (US); Alexander James TOUCHTON, Mountain View, CA (US)

(21) Appl. No.: 18/869,622

(22) PCT Filed: Jun. 14, 2023
(86) PCT No.: PCT/US2023/068419

§ 371 Date: Nov. 26, 2024

Related U.S. Application Data
(60) Provisional application No. 63/366,606, filed on Jun. 17, 2022.
(60) Provisional application No. 63/376,395, filed on Sep. 20, 2022.

(51) Int. Cl. C09D 1/00; G03F 7/00; G03F 7/004; G03F 7/36

(52) U.S. Cl. CPC C09D 1/00; G03F 7/0042; G03F 7/36; G03F 7/70033

(57) ABSTRACT

The present disclosure relates to precursor compositions for forming irradiation sensitive films. In particular, the disclosure is directed to use of metal-containing precursors having haloaliphatic or unsaturated substituents, or other reactive moieties which advantageously react in the presence of extreme ultraviolet exposure to form resist films having increased etch resistance and/or reduced shrinkage upon processing. Alternatively, the use of metal-containing precursors having haloaliphatic or unsaturated substituents, or other reactive moieties for patterning structures having carbon-containing underlayers may advantageously react with the underlayer to increase adhesion of the resist film to the underlayer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

This disclosure relates generally to the field of semiconductor processing, and in particular, to extreme ultraviolet (EUV) photoresist (PR) lithography techniques and materials.

### BACKGROUND

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. EUV radiation is strongly absorbed in a wide range of solid and fluid materials including quartz, air, and water vapor, and so operates in a vacuum.

### SUMMARY

The present disclosure relates to precursor compositions for forming irradiation sensitive films. In particular, the disclosure is directed to use of metal-containing precursors having haloaliphatic or unsaturated substituents, or other reactive moieties which advantageously react in the presence of extreme ultraviolet exposure to form resist films having increased etch resistance and/or reduced shrinkage upon processing. Alternatively, the use of metal-containing precursors having haloaliphatic or unsaturated substituents or other reactive moieties for patterning structures having carbon-containing underlayers may advantageously react with the underlayer to increase adhesion of the resist film to the underlayer.

Furthermore, use of such precursors can provide reduced film shrinkage upon radiation exposure or upon post-exposure bake. For instance, upon exposure to radiation and/or heat, such substituent groups on the precursors are generally cleaved or reacted, thereby providing increased contrast in material properties between exposed and unexposed regions. Cleavage of such groups can create a void within the film, which in turn can result in radiation- and bake-induced shrinkage effects. Accordingly, the present disclosure encompasses the use of precursors to provide films having enhanced radiation sensitivity, improved patterning quality (e.g., having improved line-width-roughness (LWR) and/or line-edge-roughness (LER)), increased film density, decreased dose to size (DtS), and/or minimized film shrinkage upon exposure to radiation, heat, or other post-patterning processes (e.g., etching).

Accordingly, in a first aspect, the present invention encompasses a precursor composition for forming an irradiation-sensitive resist film. In some embodiments, the composition includes a precursor of the formula M(R¹)₄, wherein M is a metal such as lead, germanium, tin, and hafnium, each R¹ is independently aliphatic, alkylsilyl, amino, amido, azido, cyano, alkylcarbonyl, isocyanato, isothiocyanato, thiocyanato, alkoxy, heterocyclyl, aryl, alkenyl, alkynyl, or R¹ substituents may be linked to form a ring and wherein at least one R¹ is an unsaturated substituent, with the proviso that when M is tin and each R¹ is the same, R¹ is alkynyl; wherein the precursor forms a primary metal-oxo network film having unsaturated substituents after deposition on a substrate; and wherein the unsaturated substituents in the primary metal-oxo network film form a secondary hydrocarbon network upon exposure to radiation.

In some embodiments, the secondary hydrocarbon network increases etch resistance.

In some embodiments, the secondary hydrocarbon network reduces film shrinkage after patterning.

In some embodiments, M is tin and wherein the composition comprises less than 0.5% of a tin-containing compound comprising two aliphatic R¹ substituents.

In a second aspect, the present invention encompasses a method of processing a semiconductor substrate. In some embodiments, the method includes depositing a precursor of the formula M(R¹)₄ in the presence of water, wherein M is a metal such as lead, germanium, tin, or hafnium, and each R¹ is independently aliphatic, alkylsilyl, amino, amido, azido, cyano, alkylcarbonyl, isocyanato, isothiocyanato, thiocyanato, alkoxy, heterocyclyl, aryl, alkenyl or alkynyl, or R¹ substituents may be linked to form a ring and wherein at least one R¹ is an unsaturated substituent, with the proviso that when M is tin and each R¹ is the same, R¹ is alkynyl, on a substrate to form an irradiation sensitive metal-oxo network resist film; and patterning the metal-oxo network resist film having unsaturated substituents by extreme ultraviolet exposure to form a photopatterned metal-oxo network resist film; wherein unsaturated substituents in the metal-oxo network resist film form a secondary hydrocarbon network upon exposure to radiation to form a photopatterned and cross-linked metal-oxo network resist film.

In some embodiments, the method includes dry developing the photopatterned and cross-linked metal-oxo network resist film to form a resist mask.

In some embodiments, the secondary hydrocarbon network increases etch resistance.

In some embodiments, the secondary hydrocarbon network reduces film shrinkage after patterning.

In some embodiments, M is tin.

In some embodiments, the precursor has a structure of formula (I):

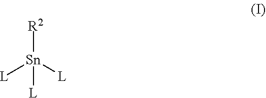

wherein R² is C₂₋₆ aliphatic; and each L is independently NR³R⁴ or OR⁵, wherein R³, R⁴ and R⁵ are each independently hydrogen, alkylcarbonyl or aliphatic, and wherein R³ and R⁴ substituents may be linked to form a ring.

In some embodiments, each L is NR³R⁴.

In some embodiments, L is dimethylamino, tert-butylamino, diethylamino, ethylmethylamino, methylpropylamino, pyrrolidino or piperidino.

In some embodiments, each L is OR⁵.

In some embodiments, L is methoxy, ethoxy, n-propoxy, iso-propoxy, tert-butoxy, sec-butoxy or n-butoxy.

In some embodiments, the unsaturated substituent is C₂-C₆ alkenyl, C₂-C₆ branched alkenyl or C₂-C₆ alkynyl.

In some embodiments, the unsaturated substituent is C₅-C₆ alkenyl, C₅-C₆ branched alkenyl or C₅-C₆ alkynyl.

In some embodiments, the precursor is vinyl tri(methoxy)tin, vinyl tri(ethoxy)tin, vinyl tri(iso-propoxy)tin, vinyl tri(tert-butoxy) tin, vinyltris(dimethylamino)tin, vinyl tris(pyrrolidino)tin, 2-propenyl tri(iso-propoxy)tin, 2-propenyl tri(tert-butoxy)tin, 2-propenyl tris(dimethylamino)tin, 2-propenyl tris(pyrrolidino)tin, 2-methyl-1-propenyl tri(iso-propoxy)tin, 2-methyl-1-propenyl tri(tert-butoxy)tin, 2-methyl-1-propenyl tris(dimethylamino)tin, 2-propenyl tris(pyrrolidino)tin, vinyl tri(1-propynyl)tin, isopropenyl tri(1-propynyl)tin, isopropenyl tris(dimethylamino)tin, 2-methyl-1-propenyl tri(1-propynyl)tin, allyl tri(iso-propoxy)tin, allyl tri(tertbutoxy)tin, allyl tris(dimethylamino)tin, allyl tris(pyrrolidino)tin, allyl tri(1-propynyl)tin, 1-methylallyl tri(iso-propoxy)tin, 1-methylallyl tri(tert-butoxy)tin, 1-methylallyl tris(dimethylamino)tin, 1-methylallyl tris(pyrrolidino)tin or 1-methylallyl tri(1-propynyl)tin.

In some embodiments, depositing also includes a second tin-containing precursor to form an upper portion of the film, thereby providing a gradient film.

In some embodiments, depositing also includes providing a counter-reactant.

In some embodiments, the counter-reactant is water vapor.

In some embodiments, the resist film is an extreme ultraviolet-sensitive film.

In some embodiments, the resist film is organotin oxy, organotin oxide, organotin oxide hydroxide, halo organotin oxy, halo organotin oxide, or halo organotin oxide hydroxide.

In some embodiments, the method also includes patterning the resist film by exposure to patterned radiation, thereby providing an exposed film having radiation exposed areas and radiation unexposed areas; and developing the exposed film, thereby removing the radiation exposed areas to provide a pattern within a positive tone resist film or removing the radiation unexposed areas to provide a pattern within a negative tone resist.

In some embodiments, patterning is an EUV exposure having a wavelength in a range of about 10 nm to about 20 nm in a vacuum ambient.

In some embodiments, developing is dry development or wet development.

In a third aspect, the present invention encompasses a precursor composition for forming an irradiation-sensitive resist film. In some embodiments, the composition includes a precursor of the formula M(R⁶)₄, wherein M is a metal such as lead, germanium, tin or hafnium; and each R⁶ is independently aliphatic, alkylsilyl, amino, amido, alkoxy, heterocyclyl, haloaliphatic, aryl or R⁶ substituents may be linked to form a ring, and wherein at least one R⁶ is a halo-containing substituent; and wherein the precursor forms a metal-oxo network resist film having halo-containing substituents and the halo-containing substituents form metal-halo bonds upon exposure to radiation.

In some embodiments, the metal-halo bonds increase etch resistance of the metal-oxo network resist film.

In some embodiments, the metal-halo bonds reduce shrinkage of the metal-oxo network resist film.

In some embodiments, M is tin and wherein the composition comprises less than 0.5% of a tin-containing compound comprising two aliphatic R⁶ substituents.

In a fourth aspect, the present invention encompasses a method of processing a semiconductor substrate. In some embodiments, the method includes depositing a precursor of the formula M(R⁶)₄ in the presence of water, wherein M is a metal such as lead, germanium, tin, or hafnium, and each R⁶ is independently aliphatic, alkylsilyl, amino, amido, azido, cyano, alkylcarbonyl, isocyanato, isothiocyanato, thiocyanato, alkoxy, heterocyclyl, haloaliphatic, aryl or R⁶ substituents may be linked to form a ring, and wherein at least one R⁶ is a halo-containing substituent, on a substrate to form an irradiation sensitive metal-oxo network resist film having halo-containing substituents; and patterning the irradiation sensitive metal-oxo network resist film having halo containing substituents by extreme ultraviolet exposure to form a photopatterned and metal-halo bond containing metal oxo network resist film.

In some embodiments, the method also includes dry developing the photopatterned and metal-halide bond containing metal-oxo network resist film to form a resist mask.

In some embodiments, M is tin.

In some embodiments, the halo-containing substituent is a beta halo containing substituent.

In some embodiments, the precursor has a structure of formula (II):

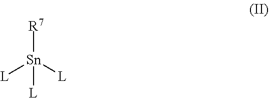

wherein R⁷ is C₂₋₆ haloaliphatic; and each L is independently NR⁸R⁹ or OR¹⁰, wherein R⁸, R⁹ and R¹⁰ are each independently hydrogen, alkylcarbonyl or aliphatic, and wherein R⁸ and R⁹ substituents may be linked to form a ring.

In some embodiments, each L is NR⁸R⁹.

In some embodiments, L is dimethylamino, tert-butylamino, diethylamino, ethylmethylamino, methylpropylamino, pyrrolidino or piperidino.

In some embodiments, each L is OR¹⁰.

In some embodiments, L is methoxy, ethoxy, n-propoxy, isopropoxy, t-butoxy, sec-butoxy or n-butoxy.

In some embodiments, R⁷ is C₅-C₆haloaliphatic.

In some embodiments, a halo of the halo-containing substituent is at least one fluorine or iodine.

In some embodiments, the precursor is 2-fluoroethyltris(dimethylamino)tin, 2-fluoroethyltris(t-butoxy)tin, 2,2-difluoroethyl tris(dimethylamino)tin, 2,2-difluoroethyl tris(t-butoxy)tin, 2,2,2-trifluoroethyl tris(dimethylamino)tin or 2,2,2-trifluoroethyl tris(t-butoxy)tin.

In some embodiments, the depositing further comprises a second tin-containing precursor to form an upper portion of the film, thereby providing a gradient film.

In some embodiments, the depositing also includes providing a counter-reactant.

In some embodiments, the counter-reactant is water vapor.

In some embodiments, the resist film is an extreme ultraviolet-sensitive film.

In some embodiments, the resist film is organotin oxy, organotin oxide, organotin oxide hydroxide, halo organotin oxy, halo organotin oxide, or halo organotin oxide hydroxide.

In some embodiments, the method also includes patterning the resist film by exposure to patterned radiation, thereby providing an exposed film having radiation exposed areas and radiation unexposed areas; and developing the exposed film, thereby removing the radiation exposed areas to provide a pattern within a positive tone resist film or removing the radiation unexposed areas to provide a pattern within a negative tone resist.

In some embodiments, the patterning is an EUV exposure having a wavelength in a range of about 10 nm to about 20 nm in a vacuum ambient.

In some embodiments, the developing is dry development or wet development.

In a fifth aspect, the present disclosure encompasses a method of making a patterning structure. In some embodiments, the method includes depositing a carbon-containing underlayer on a substrate; and depositing a tin precursor to form an irradiation sensitive tin-oxo network resist film over the carbon-containing underlayer under conditions which promote unsaturated carbon-carbon bond formation in the carbon-containing underlayer; whereby the unsaturated carbon-carbon bond formation increases adhesion of the resist film to the underlayer.

In some embodiments, increased adhesion decreases line width roughness.

In some embodiments, increased adhesion decreases dose to size.

In some embodiments, increased adhesion decreases line edge roughness.

In some embodiments, the tin precursor has a structure of formula (I):

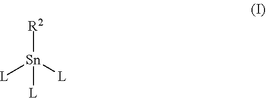

wherein R² is C₂₋₆ aliphatic; and each L is independently NR³R⁴ or OR⁵, wherein R³, R⁴ and R⁵ are each independently hydrogen, alkylcarbonyl or aliphatic, and wherein R³ and R⁴ substituents may be linked to form a ring.

In some embodiments, each L is NR³R⁴.

In some embodiments, L is dimethylamino, tert-butylamino, diethylamino, ethylmethylamino, methylpropylamino, pyrrolidino or piperidino.

In some embodiments, each L is OR⁵.

In some embodiments, L is methoxy, ethoxy, n-propoxy, iso-propoxy, tert-butoxy, sec-butoxy or n-butoxy.

In some embodiments, the unsaturated substituent is C₂-C₆ aliphatic.

In some embodiments, the unsaturated substituent is C₂-C₆ alkenyl, C₂-C₆ branched alkenyl or C₂-C₆ alkynyl.

In some embodiments, the unsaturated substituent is C₅-C₆ alkenyl, C₅-C₆ branched alkenyl or C₅-C₆ alkynyl.

In some embodiments, the tin precursor is vinyl tri(methoxy)tin, vinyl tri(ethoxy)tin, vinyl tri(iso-propoxy)tin, vinyl tri(tert-butoxy) tin, vinyltris(dimethylamino)tin, vinyl tris(pyrrolidino)tin, 2-propenyl tri(iso-propoxy)tin, 2-propenyl tri(tert-butoxy)tin, 2-propenyl tris(dimethylamino)tin, 2-propenyl tris(pyrrolidino)tin, 2-methyl-1-propenyl tri(iso-propoxy)tin, 2-methyl-1-propenyl tri(tert-butoxy)tin, 2-methyl-1-propenyl tris(dimethylamino)tin, 2-propenyl tris(pyrrolidino)tin, vinyl tri(1-propynyl)tin, isopropenyl tri(1-propynyl)tin, isopropenyl tris(dimethylamino)tin, 2-methyl-1-propenyl tri(1-propynyl)tin, allyl tri(iso-propoxy)tin, allyl tri(tertbutoxy)tin, allyl tris(dimethylamino)tin, allyl tris(pyrrolidino)tin, allyl tri(1-propynyl)tin, 1-methylallyl tri(iso-propoxy)tin, 1-methylallyl tri(tert-butoxy)tin, 1-methylallyl tris(dimethylamino)tin, i-methylallyl tris(pyrrolidino)tin or 1-methylallyl tri(1-propynyl)tin.

In some embodiments, the depositing also includes a second tin-containing precursor to form an upper portion of the film, thereby providing a gradient film.

In some embodiments, the depositing also includes providing a counter-reactant.

In some embodiments, the counter-reactant is water vapor.

In some embodiments, the resist film is an extreme ultraviolet-sensitive film.

In some embodiments, the resist film is organotin oxy, organotin oxide, organotin oxide hydroxide, halo organotin oxy, halo organotin oxide, or halo organotin oxide hydroxide.

In some embodiments, the method also includes patterning the resist film by exposure to patterned radiation, thereby providing an exposed film having radiation exposed areas and radiation unexposed areas; and developing the exposed film, thereby removing the radiation exposed areas to provide a pattern within a positive tone resist film or removing the radiation unexposed areas to provide a pattern within a negative tone resist.

In some embodiments, the patterning is an EUV exposure having a wavelength in a range of about 10 nm to about 20 nm in a vacuum ambient.

In some embodiments, the developing is dry development or wet development.

In a sixth aspect, the present invention encompasses a method of making a patterning structure. In some embodiments, the method includes depositing a carbon-containing underlayer having a surface on a substrate; and depositing a tin precursor to form an irradiation-sensitive tin-oxo network resist film over the carbon-containing underlayer under conditions which form tin-halo bonds on the surface of the carbon-containing underlayer; whereby the tin-halo bonds on the surface of the carbon-containing underlayer increase etch resistance of the resist film.

In some embodiments, the tin precursor has a structure of formula (II):

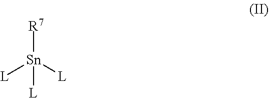

wherein R⁷ is C₂₋₆ haloaliphatic; and each L is independently NR⁸R⁹ or OR¹⁰, wherein R⁸, R⁹ and R¹⁰ are each independently hydrogen, alkylcarbonyl or aliphatic, and wherein R⁸ and R⁹ substituents may be linked to form a ring.

In some embodiments, each L is NR⁸R⁹.

In some embodiments, L is dimethylamino, tert-butylamino, diethylamino, ethylmethylamino, methylpropylamino, pyrrolidino or piperidino.

In some embodiments, each L is OR¹⁰.

In some embodiments, L is methoxy, ethoxy, n-propoxy, isopropoxy, t-butoxy, sec-butoxy or n-butoxy.

In some embodiments, R⁷ is C₅-C₆haloaliphatic.

In some embodiments, a halo of the halo-containing substituent is at least one fluorine or iodine.

In some embodiments, the tin precursor is 2-fluoroethyltris(dimethylamino)tin, 2-fluoroethyltris(t-butoxy)tin, 2,2-difluoroethyl tris(dimethylanino)tin, 2,2-difluoroethyl tris(t-butoxy)tin, 2,2,2-trifluoroethyl tris(dimethylamino)tin or 2,2,2-trifluoroethyl tris(t-butoxy)tin.

In some embodiments, increased etch resistance decreases dose to size.

In some embodiments, the deposition also includes a second tin-containing precursor to form an upper portion of the film, thereby providing a gradient film.

In some embodiments, the depositing also includes providing a counter-reactant.

In some embodiments, the counter-reactant is water vapor.

In some embodiments, the resist film is an extreme ultraviolet-sensitive film.

In some embodiments, the resist film is organotin oxy, organotin oxide, organotin oxide hydroxide, halo organotin oxy, halo organotin oxide, or halo organotin oxide hydroxide.

In some embodiments, the method also includes patterning the resist film by exposure to patterned radiation, thereby providing an exposed film having radiation exposed areas and radiation unexposed areas; and developing the exposed film, thereby removing the radiation exposed areas to provide a pattern within a positive tone resist film or removing the radiation unexposed areas to provide a pattern within a negative tone resist.

In some embodiments, the patterning is an EUV exposure having a wavelength in a range of about 10 nm to about 20 nm in a vacuum ambient.

In some embodiments, the developing is dry development or wet development.

In a seventh aspect, the present invention encompasses a patterning radiation-sensitive film. In some embodiments, the film includes an organometal-oxo material, wherein the material includes: a metal, oxygen, and an alkylsilyl, heterocyclyl or aryl.

In some embodiments, the alkylsilyl is trimethylsilyl, triethylsilyl, tert-butyldimethylsilyl, ethyldimethylsilyl or tri-isopropylsilyl.

In some embodiments, the aryl is phenyl, benzyl or methylcyclopentadienyl.

In some embodiments, the heterocyclyl is imidazolyl, pyrrolidinyl, pyridinyl, tetrahydrofuranyl, tetrahydropyranyl or dioxanyl.

In some embodiments, the organo-metal oxo material has a network of metal-oxygen bonds and metal-alkylsilyl or metal-heterocyclyl bonds.

In some embodiments, the patterning radiation-sensitive film is an extreme ultraviolet-sensitive film.

In some embodiments, the metal is tin.

In an eighth aspect, the present invention encompasses a patterning radiation-sensitive film. In some embodiments, the film includes an organotin-oxo material, wherein an orgaontin-oxo material includes: tin, oxygen, and a C₅₋₆ aliphatic or C₅₋₆ haloaliphatic.

In some embodiments, the C₅₋₆ haloaliphatic is C₅₋₆ haloalkyl, C₅₋₆ haloalkenyl or C₅₋₆ haloalkynyl.

In some embodiments, the C₅₋₆ haloaliphatic is one or more halo substitutions.

In some embodiments, the C₅₋₆ aliphatic is pentyl, pentenyl, pentynyl, hexyl, hexenyl or hexynyl.

In some embodiments, the C₅₋₆ aliphatic is cyclopentyl, cyclohexyl, cyclopentenyl, cyclohexenyl or cyclohexadienyl.

In some embodiments, the material is a network of tin-oxygen bonds and tin-C₅₋₆ aliphatic or tin-C₅₋₆ haloaliphatic bonds.

In a nineth aspect, the present invention encompasses a precursor composition for forming an irradiation-sensitive resist film. In some embodiments, the composition includes a tin precursor of formula (III) or (IV):

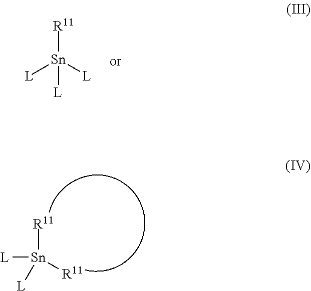

wherein R¹¹ is alkylsilyl, amino, amido, alkoxy, heterocyclyl, aryl, C₅₋₆ aliphatic or C₅₋₆ haloaliphatic or R¹¹ substituents may be linked to form a ring; and each L is independently NR¹²R¹³ or OR¹⁴, wherein R¹², R¹³ and R¹⁴ are each independently hydrogen, alkylcarbonyl or aliphatic, and wherein R¹² and R¹³ substituents may be linked to form a ring; wherein the precursor forms a primary tin-oxo network film after deposition on a substrate; and wherein the primary tin-oxo network film forms a secondary hydrocarbon network upon exposure to radiation.

In some embodiments, the secondary hydrocarbon network increases etch resistance.

In some embodiments, the secondary hydrocarbon network reduces film shrinkage after patterning.

In some embodiments, each L is NR¹²R¹³.

In some embodiments, L is dimethylamino, tert-butylamino, diethylamino, ethylmethylamino, methylpropylamino, pyrrolidino or piperidino.

In some embodiments, the tin precursor has a structure of formula (III) and each L is OR¹⁴.

In some embodiments, L is methoxy, ethoxy, n-propoxy, isopropoxy, t-butoxy, sec-butoxy or n-butoxy.

In a tenth aspect, the present invention encompasses a method of employing a resist.

In some embodiments, the method includes depositing a tin-containing precursor on a surface of a substrate to provide a tin oxide resist film, wherein the tin-containing precursor comprises a structure of formula (III) or (IV):

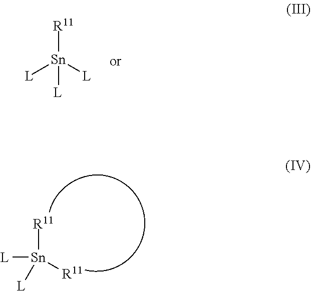

wherein R¹¹ is alkylsilyl, amino, amido, alkoxy, heterocyclyl, aryl, C₅₋₆ aliphatic or C₅₋₆ haloaliphatic or R¹¹ substituents may be linked to form a ring; and each L is independently NR¹²R¹³ or OR¹⁴, wherein R¹², R¹³ and R¹⁴ are each independently hydrogen, alkylcarbonyl or aliphatic, and wherein R¹² and R¹³ substituents may be linked to form a ring.

In some embodiments, each L is NR¹²R¹³.

In some embodiments, L is dimethylamino, tert-butylamino, diethylamino, ethylmethylamino, methylpropylamino, pyrrolidino or piperidino.

In some embodiments, the tin precursor has a structure of formula (III) and each L is OR¹⁴.

In some embodiments, L is methoxy, ethoxy, n-propoxy, isopropoxy, t-butoxy, sec-butoxy or n-butoxy.

In some embodiments, the depositing also includes a second tin-containing precursor to form an upper portion of the film, thereby providing a gradient film.

In some embodiments, the depositing also includes providing a counter-reactant.

In some embodiments, the counter-reactant is water vapor.

In some embodiments, the tin oxide resist film is an extreme ultraviolet-sensitive film.

In some embodiments, the tin oxide resist film is organotin oxy, organotin oxide, organotin oxide hydroxide, halo organotin oxy, halo organotin oxide, or halo organotin oxide hydroxide.

In an eleventh aspect, the present invention encompasses a precursor composition for forming an irradiation-sensitive resist film. In some embodiments, the composition includes a precursor of formula (V), (VI) or (VII):

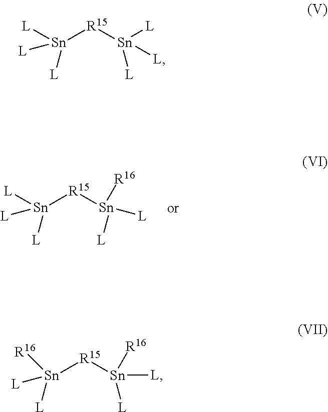

wherein R¹⁵ is (C(R¹⁷)₂)ₙ, wherein each R¹⁷ is independently hydrogen or aliphatic, or R¹⁷ substituents may be linked to form a ring, and n is an integer of 1 to 10; each R¹⁶ is independently alkylsilyl, amino, heterocyclyl, aryl, C₅₋₆ aliphatic or C₅₋₆ haloaliphatic or R⁷ substituents may be linked to form a ring; and each L is independently NR¹⁷R¹⁸ or OR¹⁹, wherein R¹⁷, R¹⁸ and R¹⁹ are each independently hydrogen or aliphatic, or R¹⁷ and R¹⁸ substituents may be linked to form a ring; wherein the precursor forms a primary tin-oxo network film after deposition on a substrate; and wherein the primary tin-oxo network film forms a secondary hydrocarbon network upon exposure to radiation.

In some embodiments, the secondary hydrocarbon network increases etch resistance.

In some embodiments, the secondary hydrocarbon network reduces film shrinkage after patterning.

In some embodiments, each L is NR¹⁷R¹⁸.

In some embodiments, L is dimethylamino, tert-butylamino, diethylamino, ethylmethylamino, methylpropylamino, pyrrolidino or piperidino.

In some embodiments, each L is OR¹⁹.

In some embodiments, L is methoxy, ethoxy, n-propoxy, isopropoxy, t-butoxy, sec-butoxy or n-butoxy.

In a twelfth aspect, the present invention encompasses a method of employing a resist.

In some embodiments, the method includes depositing a tin-containing precursor on a surface of a substrate to provide a tin oxide resist film, wherein the tin-containing precursor comprises a structure of formula (V), (VI) or (VII):

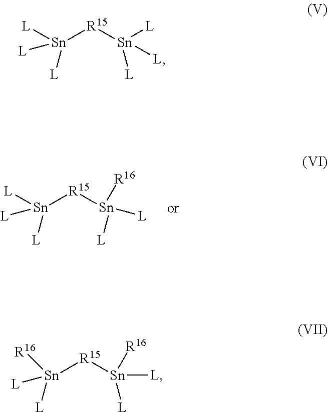

wherein R¹⁵ is (C(R¹⁷)₂)ₙ, wherein each R¹⁷ is independently hydrogen or aliphatic, or R¹⁷ substituents may be linked to form a ring, and n is an integer of 1 to 10; each R¹⁶ is independently alkylsilyl, amino, heterocyclyl, aryl, C₅₋₆ aliphatic or C₅₋₆ haloaliphatic or R⁷ substituents may be linked to form a ring; and each L is independently NR¹⁷R¹⁸ or OR¹⁹, wherein R¹⁷, R¹⁸ and R¹⁹ are each independently hydrogen or aliphatic, or R¹⁷ and R's substituents may be linked to form a ring.

In some embodiments, each L is NR¹⁷R¹⁸.

In some embodiments, L is dimethylamino, tert-butylamino, diethylamino, ethylmethylamino, methylpropylamino, pyrrolidino or piperidino.

In some embodiments, each L is OR¹⁹.

In some embodiments, L is methoxy, ethoxy, n-propoxy, isopropoxy, t-butoxy, sec-butoxy or n-butoxy.

In some embodiments, the depositing also includes a second tin-containing precursor to form an upper portion of the film, thereby providing a gradient film.

In some embodiments, wherein the depositing also includes providing a counter-reactant.

In some embodiments, the counter-reactant is water vapor.

In some embodiments, the resist film is an extreme ultraviolet-sensitive film.

In some embodiments, the tin oxide resist film is organotin oxy, organotin oxide, organotin oxide hydroxide, halo organotin oxy, halo organotin oxide, or halo organotin oxide hydroxide.

In some embodiments, the method also includes patterning the resist film by exposure to patterned radiation, thereby providing an exposed film having radiation exposed areas and radiation unexposed areas; and developing the exposed film, thereby removing the radiation exposed areas to provide a pattern within a positive tone resist film or removing the radiation unexposed areas to provide a pattern within a negative tone resist.

In some embodiments, the patterning is an EUV exposure having a wavelength in a range of about 10 nm to about 20 nm in a vacuum ambient.

In some embodiments, the developing is dry development or wet development.

In some embodiments, the dry development is employed with an exposed film comprising tin bonded to fluorine or iodine atoms.

In a thirteenth aspect, the present invention encompasses a method for deposition of a tin oxide resist film on a surface of a substrate including reacting a tin compound with an acetamide or an alcohol to form a tin precursor comprising the formula Sn(NR²⁰R²¹)₄ or Sn₂(NR²⁰R²¹)₄, wherein R²⁰ and R²¹ are each independently hydrogen or aliphatic, or R²⁰ and R²¹ substituents may be linked to form a ring; depositing the tin precursor on the surface of the substrate; exposing the tin precursor on the surface of the substrate to extreme ultraviolet radiation; and forming a tin oxide resist film.

In some embodiments, the acetamide is acetamide, N-methylacetamide, N-ethylacetamide, N-methylformamide, N-ethylformamide, M-methylpropionamide or propanamide.

In some embodiments, the alcohol is methanol, ethanol, butanol, t-butanol, isopropanol or propanol.

In some embodiments, R²⁰ and R²¹ are each independently aliphatic.

In some embodiments, the tin compound is tetrakis(dimethylamino)tin or bis(dimethylamino)tin(II) dimer.

In a fourteenth aspect, the present invention encompasses an apparatus for forming a resist film. In some embodiments, the apparatus includes a deposition module comprising a chamber for depositing an irradiation sensitive resist film; and a controller including one or more memory devices, one or more processors, and system control software coded with instructions comprising machine-readable instructions for: in the deposition module, causing deposition of a metal-containing precursor and an optional ligand-containing precursor on a top surface of a semiconductor substrate to form the resist film, wherein the resist film comprises a metal, an oxygen, and an alkylsilyl, heterocyclyl or aryl.

In some embodiments, the resist film comprises an extreme ultraviolet-sensitive film.

In some embodiments, the apparatus also includes a patterning module including a photolithography tool with a source of sub-300 nm wavelength radiation, wherein the instructions comprising machine-readable instructions further comprises instructions for: in the patterning module, causing patterning of the resist film with sub-300 nm resolution directly by patterning radiation exposure, thereby forming an exposed film having radiation exposed areas and radiation unexposed areas.

In some embodiments, the source for the photolithography tool is a source of sub-30 nm wavelength radiation.

In any embodiment herein, said depositing includes providing a metal-containing precursor in vapor form. In other embodiments, said depositing includes providing a metal-containing precursor, a ligand-containing precursor, and/or a counter-reactant in vapor form. Non-limiting deposition processes include chemical vapor deposition (CVD), as well as atomic layer deposition (ALD), molecular layer deposition (MLD), and plasma-enhanced forms thereof.

In any embodiment herein, said depositing further includes providing a counter-reactant. Non-limiting counter-reactants include an oxygen-containing or a chalcogenide-containing precursor, as well as any described herein (e.g., an oxygen-containing counter-reactant, including oxygen (O₂), ozone (O₃), water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof). Additional details follow.

### Definitions

By “aliphatic” is meant a hydrocarbon moiety having at least one carbon atom to 50 carbon atoms (C₁₋₅₀), such as one to 25 carbon atoms (C₁₋₂₅), or one to ten carbon atoms (C₁₋₁₀), and which includes saturated groups such as alkanes (or alkyl) and unsaturated groups such as alkenes (or alkenyl), alkynes (or alkynyl), and also includes cyclic versions thereof, and further including straight- and branched-chain arrangements, and all stereo and position isomers as well. Such a hydrocarbon can be unsubstituted or substituted with one or more groups, such as halogens or groups described herein for an alkyl group.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include C₂₋₈ alkenyl, C₂₋₆ alkenyl, C₂₋₅ alkenyl, C₂₋₄ alkenyl, or C₂₋₃ alkenyl. Exemplary, non-limiting alkenyl groups include vinyl or ethenyl (—CH═CH₂), 1-propenyl (—CH═CHCH₃), allyl or 2-propenyl (—CH₂—CH═CH₂), 1-butenyl (—CH═CHCH₂CH₃), 2-butenyl (—CH₂CH═CHCH₃), 3-butenyl (e.g. —CH₂CH₂CH═CH₂), 2-butenylidene (e.g., ═CH—CH═CHCH₃), and the like.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr or nPr), isopropyl (i-Pr or iPr), cyclopropyl, n-butyl (n-Bu or nBu), isobutyl (i-Bu or iBu), s-butyl (s-Bu or sBu), t-butyl (t-Bu or tBu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 3-, 4-, 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15) N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₂, C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkylcarbonyl” is meant an alkyl group as previously defined appended to the parent molecular moiety through a carbonyl group. Exemplary, non-limiting alkylcarbonyl groups include methylcarbonyl, ethylcarbonyl, and isopropylcarbonyl among others.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. Non-limiting unsubstituted alkynyl groups include C₂₋₈ alkynyl, C₂₋₆ alkynyl, C₂₋₅ alkynyl, C₂₋₄ alkynyl, or C₂₋₃ alkynyl. Exemplary, non-limiting alkynyl groups include ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), and the like.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amido” is meant —N(R^{N1})C(O)—, where R^{N1} is H, optionally substituted alkyl, or optionally substituted aryl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aminoaryl” is meant an aryl group, as defined herein, substituted by an amino group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “azido” is meant —N₃.

By “branched alkenyl” is meant an isomer of a straight chain alkenyl compound; one having alkyl groups bonded to the main carbon chain.

By “cyano” is meant —CN.

By “carbonyl” is meant a —C(O)— group, which can also be represented as >C═O.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “deposition” or “vapor deposition” is meant a process in which a metal layer is formed on one or more surfaces of a substrate from vaporized precursor composition(s) including one or more metal containing compounds. The metal-containing compounds are vaporized and directed to and/or contacted with one or more surfaces of a substrate (i.e., semiconductor substrate or semiconductor assembly) placed in a deposition chamber. Typically, the substrate is heated. These metal containing compounds form a non-volatile, thin, uniform metal-containing layer on the surface(s) of the substrate. One operation of the method is one cycle, and the process can be repeated for as many cycles necessary to obtain the desired metal thickness.

By “dicarbonyl” is meant any moiety or compound including two carbonyl groups, as defined herein. Non-limiting dicarbonyl moieties include 1,2-dicarbonyl (e.g., R^{C1}—C(O)—C(O)R^{C2}, in which each of R^{C1} and R^{C2} is, independently, optionally substituted alkyl, halo, optionally substituted alkoxy, hydroxyl, or a leaving group); 1,3-dicarbonyl (e.g., R^{C1}—C(O)—C(R^{1a}R^{2a})—C(O)R^{C2}, in which each of R^{C1} and R^{C2} is, independently, optionally substituted alkyl, halo, optionally substituted alkoxy, hydroxyl, or a leaving group and in which each of R^{1a} and R^{2a} is, independently, H or an optional substituent provided for alkyl, as defined herein); and 1,4-dicarbonyl (e.g., R^{C1}—C(O)—C(R^{1a}R^{2a})—C(R^{3a}R^{4a})—C(O)R^{C2}, in which each of R^{C1} and R^{C2} is, independently, optionally substituted alkyl, halo, optionally substituted alkoxy, hydroxyl, or a leaving group and in which each of R^{1a}, R^{2a}, R^{3a}, and R^{4a} is, independently, H or an optional substituent provided for alkyl, as defined herein).

By “halo” is meant F, Cl, Br, or I.

By “halo containing substituent” is meant a group that contains a halo, such as a haloaliphatic or haloalkyl group.

By “haloaliphatic” is meant an aliphatic group, as defined herein, substituted with one or more halo.

By “haloalkenyl” is meant an alkenyl group, as defined herein, substituted with one or more halo.

By “haloalkynyl” is meant an alkynyl group, as defined herein, substituted with one or more halo.

By “haloalkyl” is meant an alkyl group, as defined herein, substituted with one or more halogen. Non-limiting unsubstituted haloalkyl groups include C₁₋₂ haloalkyl, C₁₋₃ haloalkyl, C₁₋₄ haloalkyl, C₁₋₅ haloalkyl, C₁₋₆ haloalkyl, C₂₋₃ haloalkyl, C₂₋₄ haloalkyl, C₂₋₅ haloalkyl, C₂₋₆ haloalkyl, or C₃₋₆ haloalkyl. Other non-limiting haloalkyl groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; —CH₂CX_{y}H_{3-y}, wherein y is 1, 2, or 3, and wherein each X is, independently, halo (F, Cl, Br, or I); —CX_{z1}H_{2-z1}CX_{z2}H_{2-z2}CX_{y}H_{3-y}, wherein each of z1 and z2 is, independently, 0, 1, or 2, wherein y is 0, 1, 2, or 3, and wherein each X is, independently, halo (F, Cl, Br, or I), in which at least one of z1, z2, or y is not 0; and —CX_{z}H_{1-z}[CX_{y1}H_{3-y1}][CX_{y2}H_{3-y2}], wherein z is 0 or 1, wherein each of y1 and y2 is, independently, 0, 1, 2, or 3, and wherein each X is, independently, halo (F, Cl, Br, or I), in which at least one of z, y1, or y2 is not 0.

By “haloalkylene” is meant an alkylene group, as defined herein, substituted with one or more halo.

By “heterocyclyl” is meant a 3-, 4-, 5-, 6- or 7-membered ring, unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl, benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “imino” is meant —NR—, in which R can be H or optionally substituted alkyl.

By “isocyanato” is meant —NCO.

By “isothiocyanato” is meant —N═C═S.

By “oxo” is meant an ═O group.

By “oxy” is meant —O—.

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

Use of the above terms is meant to encompass substituted and unsubstituted moieties. Substitution may be by one or more groups such as alcohols, ethers, esters, amides, sulfones, sulfides, hydroxyl, nitro, cyano, carboxy, amines, heteroatoms, lower alkyl, lower alkoxy, lower alkoxycarbonyl, alkoxyalkoxy, acyloxy, halogens, trifluoromethoxy, trifluoromethyl, alkyl, aralkyl, alkenyl, alkynyl, aryl, cyano, carboxy, carboalkoxy, carboxyalkyl, cycloalkyl, cycloalkylalkyl, heterocyclyl, alkylheterocyclyl, heterocyclylalkyl, oxo, arylsulfonyl and aralkyaminocarbonyl, or any of the substituents of the preceding paragraphs or any of those substituents either directly attached or by suitable linkers. The linkers are typically short chains of 1-3 atoms containing any combination of —C—, —C(O)—, —NH—, —S—, —S(O)—, —O—, —C(O)— or —S(O)O—. Rings may be substituted multiple times.

The term “lower” modifying “alkyl”, “alkenyl”, “alkynyl”, “alkoxy” or “alkoxycarbonyl” refers to a C₁-C₆ unit for a particular functionality. For example, “lower alkyl” means C₁-C₆ alkyl.

By “substituted” is meant having one or more substituent moieties whose presence does not interfere with the desired function or reactivity. Examples of substituents alkyl, alkenyl, alkynyl, cycloalkyl (non-aromatic ring), Si(alkyl)₃, Si(alkoxy)₃, alkoxy, amino, alkylamino, alkenylamino, amide, amidine, guanidine, hydroxyl, thioether, alkylcarbonyl, alkylcaronyloxy, alkoxycarbonyloxy, carbonate, alkoxycarbonyl, aminocarbonyl, alkylthiocarbonyl, phosphate, phosphate ester, phosphonato, cyano, halo, acylamino, imino, sulfhydryl, alkylthio, thiocarboxylate, dithiocarboxylate, sulfate, sulfato, sulfonate, sulfamoyl, sulfonamide, nitro, nitrile, azido, heterocyclyl, ether, ester, silicon-containing moieties, thioester or a combination thereof. The substituents may themselves be substituted. For instance, an amino substituent may itself be mono or independently disubstituted by further substituents defined above, such as alkyl, alkenyl, alkynyl, and cycloalkyl (non-aromatic ring).

By “thiocyanato” is meant —SCN.

By “unsubstituted” is meant any open valence of an atom being occupied by hydrogen. Also, if an occupant of an open valence position on an atom is not specified, then it is hydrogen.

As used herein, the term “about” is understood to account for minor increases and/or decreases beyond a recited value, which changes do not significantly impact the desired function of the parameter beyond the recited value(s). In some cases, “about” encompasses+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like.

“Tin oxide” is referred to herein as including any and all stoichiometric possibilities for SnₓO_{y}, including integer values of x and y and non-integer values of x and y. For example, “tin oxide” includes compounds having the formula SnOₙ, where 1≤n≤2, where n can be an integer or non-integer values. “Tin oxide” can include sub-stoichiometric compounds such as SnO_{1.8}. “Tin oxide” also includes tin dioxide (SnO₂ or stannic oxide) and tin monoxide (SnO or stannous oxide). “Tin oxide” also includes both natural and synthetic variations and also includes any and all crystalline and molecular structures. “Tin oxide” also includes amorphous tin oxide.

By “unsaturated” is meant a moiety that contains double or triple carbon-carbon bonds.

By “unsaturated substituent” is meant a double or triple bond containing aliphatic chain, cyclic, aryl or heteroaryl group.

Other features and advantages of the invention will be apparent from the following description and the claims.

### BRIEF DESCRIPTION OF THE DRAWINGS

FIG. 1 presents a flow diagram of a non-limiting method that employs a resist film. Provided is a schematic of a non-limiting method 100 including depositing 101 a metal-containing precursor 30 with an optional ligand-containing precursor 32 in accordance with certain disclosed embodiments.

FIG. 2 presents a flow diagram of a non-limiting method that employs a resist film. Provided is a flow diagram of another non-limiting method 200 in accordance with certain disclosed embodiments.

FIG. 3A presents a reaction scheme illustrating tin-oxo network formation from an alkenyl-substituent containing tin precursor in accordance with certain disclosed embodiments.

FIG. 3B presents a reaction scheme illustrating tin-oxo network formation from a haloaliphatic-substituent containing tin precursor in accordance with certain disclosed embodiments.

FIG. 4A presents an FTIR spectrum of tin-oxo network formed from an alkenyl-substituent containing tin precursor and exposed to UV in accordance with certain disclosed embodiments.

FIG. 4B presents another Fourier-transform infrared (FTIR) spectrum of tin-oxo network formed from an alkenyl-substituent containing tin precursor and exposed to UV in accordance with certain disclosed embodiments.

FIG. 4C presents a scanning electron microscope (SEM) image of a tin-oxo network film formed from an alkenyl-substituent containing tin precursor after processing in accordance with certain disclosed embodiments.

FIG. 5A presents a table of x-ray photoelectron spectroscopy (XPS) data for a tin-oxo network film formed from a haloaliphatic-substituent containing tin precursor before and after processing in accordance with certain disclosed embodiments.

FIG. 5B presents a scanning electron microscope (SEM) image of a tin-oxo network film formed from a haloaliphatic-substituent containing tin precursor after processing in accordance with certain disclosed embodiments.

FIG. 6 presents a flow diagram of a non-limiting method that employs a resist film and an underlayer. Provided is a schematic of non-limiting method 300 including depositing 306 a metal-containing precursor in accordance with certain disclosed embodiments.

FIG. 7 presents a schematic illustration of a tin-oxo network formed from an alkenyl-substituent containing tin precursor interacting with a carbon-based underlayer in accordance with certain disclosed embodiments.

FIG. 8 presents a schematic illustration of a tin-oxo network film formed from a haloaliphatic-substituent containing tin precursor interacting with a carbon-based underlayer in accordance with certain disclosed embodiments.

FIG. 9 presents a schematic illustration of an embodiment of a process station 400 for dry development.

FIG. 10 presents a schematic illustration of an embodiment of a multi-station processing tool 500.

FIG. 11 presents a schematic illustration of an embodiment of an inductively coupled plasma apparatus 600.

FIG. 12 presents a schematic illustration of an embodiment of a semiconductor process cluster tool architecture 700.

### DETAILED DESCRIPTION

The present disclosure relates to precursor compositions for forming irradiation sensitive films. In particular, the disclosure is directed to use of metal-containing precursors having haloaliphatic or unsaturated substituents, or other reactive moieties which advantageously react in the presence of extreme ultraviolet exposure to form resist films having increased etch resistance and/or reduced shrinkage upon processing. Alternatively, the use of metal-containing precursors having haloaliphatic or unsaturated substituents or other reactive moieties for patterning structures having carbon-containing underlayers may advantageously react with the underlayer to increase adhesion of the resist film to the underlayer.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

EUV lithography makes use of EUV resists that are patterned to form masks for use in etching underlying layers. EUV resists may be polymer-based chemically amplified resists (CARs) produced by liquid-based spin-on techniques or dry-vapor deposited. An alternative to CARs is directly photopatternable metal oxide-containing films, such as those available from Inpria Corp. (Corvallis, OR), and described, for example, in U.S. Pat. Pub. Nos. US 2017/0102612, US 2016/0216606, and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in International Appl. No. PCT/US19/31618, published as International Pub. No. WO2019/217749, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the hardmask.

Directly photopatternable EUV or DUV resists may be composed of or contain metals and/or metal oxides mixed within organic components. The metals/metal oxides are highly promising in that they can enhance the EUV or DUV photon adsorption, generate secondary electrons, and/or show increased etch selectivity to an underlying film stack and device layers. Up to date, these resists have been developed using a wet (solvent) approach, which requires the wafer to move to the track, where it is exposed to developing solvent, dried, and then baked. This wet development step does not only limit productivity but can also lead to line collapse due to surface tension effects during the evaporation of solvent between fine features.

Generally, resists can be employed as a positive tone resist or a negative tone resist by controlling the chemistry of the resist and/or the solubility or reactivity of the developer. It would be beneficial to have a EUV or DUV resist that can serve as either a negative tone resist or a positive tone resist.

### Resist Films and Methods Thereof

The present disclosure relates to organometallic resist films and methods thereof. In particular embodiments, the film includes a halogen-containing organometallic material. Such materials can provide compact or dense films, which in turn exhibit improved radiation absorptivity and limited bake-induced and radiation-induced shrinkage. Dense films can be realized by employing precursors having a radiation-cleavable group that is relatively small. Such groups can be, for example, a C₁₋₂ (halo)aliphatic group. As compared to cleavage of a larger groups (e.g., a C₃₋₁₂ aliphatic group), cleavage and release of the smaller C₁₋₂ (halo)aliphatic group will create a smaller void (where the group once resided) upon exposure. Such voids can contribute to film shrinkage when the exposed film is further treated (e.g., by way of a post-exposure, a post-exposure etch, or other processes). By minimizing the size of the voids, film shrinkage can be minimized.

Film shrinkage can contribute to various undesired effects. For instance, when exposed areas shrink dramatically, this results in higher dose-to-size (DtS) and can limit the applicability of such resists as etch hardmasks. Thus, the films herein can be employed to avoid film shrinkage. Such films can provide, e.g., decreased DtS after subsequent development and/or use as an etch hardmask.

Radiation absorption can also be improved. For instance, the smaller size of the radiation-cleavable group could provide a denser film, thereby providing additional atoms for radiation absorption (e.g., on a per cm⁻² basis). In addition, halogen atoms have higher EUV absorptivity, as compared to hydrogen atoms. Thus, the presence of halogen substituents on the radiation-cleavable group can provide an EUV light-sensitive moiety having increased absorptivity. In other embodiments, the haloaliphatic groups or halo atoms from such groups are incorporated into the film, in which halogen have higher EUV absorptivity than hydrogen. Such groups (e.g., haloaliphatic groups or halo atoms) can be provided attached to a metal atom, bridging two metal atoms, or attached to a ligand. Films having higher absorption can provide, e.g., decreased line width roughness (LWR) after subsequent development but without requiring higher doses; and a thinner film that is not limited by a minimal thickness to provide sufficient absorption and effective pattern formation. Such thin films could be processed by using optical applications having a shallow depth-of-focus.

A metal-containing precursor can be used alone or, alternatively, with additional precursors, such as a ligand-containing precursor to further modify the functional groups attached to M in the metal-containing precursor. The ligand-containing precursor can react with the metal-containing precursor to install additional L and/or R groups on M.

By combining such metal- and ligand-containing precursors, further metal-containing precursors can be provided. In this way, the final combination of cleavable groups (R) and/or ligands (L) can be modified, either in situ (within the chamber) or prior to delivery to the chamber for deposition.

Ligand-containing precursors can include an organolithium compound (e.g., LiL), an organosodium compound (e.g., NaL), an organomagnesium compound (e.g., MgL₂), a Grignard reagent (e.g., MgLX, in which X is halo), an organozinc compound (e.g., ZnL₂), or an organoaluminum compound (e.g., AlL₃). In particular embodiments, such reagents are not employed within a deposition chamber but employed to synthesize the precursor prior to delivery to the deposition chamber.

Useful ligands in the ligand-containing precursor can include any described herein, including an organic moiety (e.g., optionally substituted alkyl, optionally substituted amino, optionally substituted alkoxy, optionally substituted bis(trialkylsilyl)amino (e.g., —N(SiMe₃)₂), optionally substituted trialkylsilyl, or others). Other ligand-containing precursors can include an aliphatic halide (e.g., RX, in which X is halo and R is an optionally substituted alkyl) or a haloaliphatic halide (e.g., RX, in which X is halo and R is an optionally substituted haloalkyl). Non-limiting R groups include an optionally substituted C₁₋₂ haloalkyl, such as —CX_{z}H_{3-z} or —CH₂CX_{z}H_{3-z}, in which z is 1, 2, or 3; and an optionally substituted C₁₋₄ alkyl, such as —CₙH₂ₙ₊₁, in which n is 1 or 2; or such as —CₙH₂ₙ₋₁ or —CₙH₂ₙ₋₃, in which n is 2, 3, or 4.

The present disclosure also generally includes any useful method that employs a metal-containing precursor with an optional ligand-containing precursor, as described herein. Such methods can include any useful lithography processes, deposition processes, radiation exposure processes, development processes, and post-application processes, as described herein. While the following may describe techniques as relating to EUV processes, such techniques may also be applicable to other next generation lithographic techniques. Various radiation sources may be employed, including EUV (generally about 13.5 nm), DUV (deep-UV, generally in the 248 nm or 193 nm range with excimer laser sources), X-ray (including EUV at the lower energy range of the X-ray range), and e-beam (including a wide energy range).

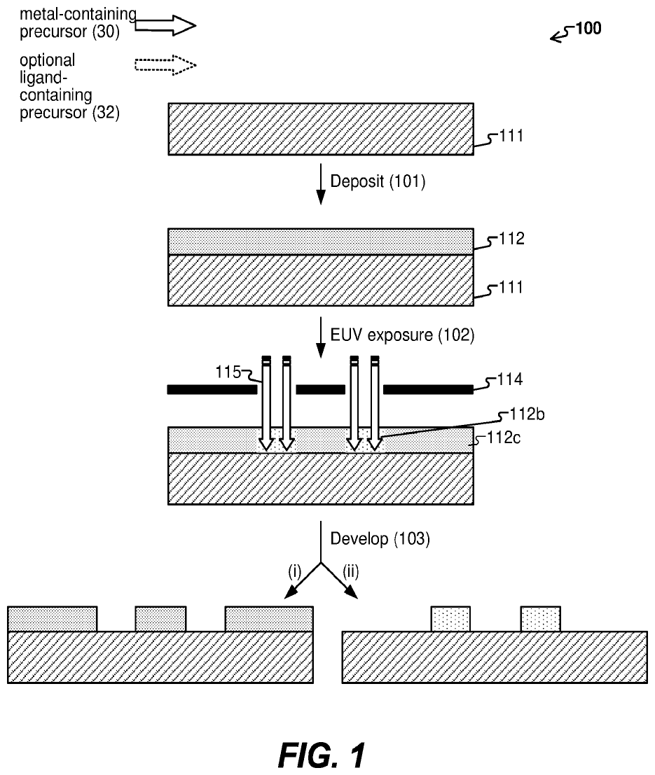

Exemplary methods can include delivery of metal-containing precursor(s) to a substrate, as well as simultaneous or sequential delivery of metal-containing precursor(s) and ligand-containing precursor(s) to a substrate. For example, FIG. 1 provides a non-limiting process 100 that includes depositing 101 the metal-containing precursor 30 and the optional ligand-containing precursor 32 on a substrate 111. Such co-deposition can provide a dense, film 112 having a matrix of metal atoms and (halo)aliphatic constituents or aliphatic. Such deposition can include dry deposition.

When a ligand-containing precursor is employed, delivery of the metal- and ligand-containing precursor can occur in any useful order. When delivery sequentially, an optional operation can include purging the chamber to remove un-reacted precursors. Such purging can include use of an inert gas to remove metal- or ligand-containing precursors present in vapor form and, thus, not deposited on the substrate.

Such films can be deposited in any useful manner, as described herein. Exemplary deposition techniques include chemical vapor deposition (CVD), plasma enhanced CVD (PE-CVD), low pressure CVD (LP-CVD), atomic layer deposition (ALD) (e.g., thermal ALD and plasma-enhanced ALD (PE-ALD)), molecular layer deposition (MLD), spin-coat deposition, physical vapor deposition (PVD) including PVD co-sputtering, sputter deposition, electron-beam (e-beam) deposition including e-beam co-evaporation, etc., or a combination thereof. Other deposition processes and conditions are described herein.

The metal- and/or ligand-containing precursors can be optionally deposited in the presence of one or more counter-reactants. Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as O₂, O₃, water, peroxides (e.g., hydrogen peroxide), oxygen plasma, water plasma, alcohols, di- or polyhydroxy alcohols, acetamides, fluorinated di- or polyhydroxy alcohols, fluorinated glycols, formic acid, and other sources of hydroxyl moieties, as well as combinations thereof. In various embodiments, a counter-reactant reacts with the metal- and/or ligand-containing precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film. Yet other counter-reactants can include any chalcogenide-containing precursors or chalcogenide-containing compounds described herein.

Various process conditions for deposition can be varied and optimized. For instance, deposition (e.g., of the metal- and/or ligand-containing precursors) can be performed at a temperature between about 20-400° C., such as about 50-300° C., about 100-200° C., or about 150° C. In some embodiments, the metal- and/or ligand-containing precursor(s) have thermal decomposition points that are higher than the process temperature, so as to yield self-limiting surface reactions. Non-limiting pressure conditions include in the range of about 0.1-50 Torr, such as about 1-15 Torr. In some embodiments, the metal- and/or ligand-containing precursor(s) have vapor pressures that are greater than 0.5 Torr at 100° C. or less.

The process step time for each operation can include the following ranges: a metal-containing precursor dose of from about 0.1-10 seconds; a ligand-containing precursor dose of from about 0.1-60 seconds; and a purge period of from about 0.1-60 seconds.

Deposition can be repeated for any number of cycles. Each cycle can include a deposition operation, which can include deposition of a metal-containing precursor; co-deposition of metal- and ligand-containing precursors; or sequential deposition of metal- and ligand-containing precursors with optional purge operations. Such cycles can be repeated for any useful number of cycles, e.g., 1-1000 cycles to deposit the desired film thickness.

When the desired film thickness is deposited, post-deposition treatment steps may be performed. In one instance, such post-deposition treatment involves exposing the film to a long dose (or soak) with a soak precursor. The soak can be used to increase the EUV absorbance of the film. In one embodiment, the soak precursor is a metal-containing precursor, and use of this soak precursor increases the concentration of metal atoms in the film. In other embodiments, the soak precursor is the ligand-containing precursor. The soak precursor can be the same or different from the metal-containing precursor used in the deposition process. The soak may be performed under similar conditions as the deposition process, but generally the dose time may be relatively longer, such as in the range of 30 seconds to 30 minutes.

The methods herein can include deposition directly onto a substrate or onto a layer disposed on a surface of the substrate. In one instance, the substrate can include an adhesion layer or an underlayer, which can be an organic underlayer or an intermediate etch layer.

The resist film can have any useful structure. In one embodiment, the film has a thickness of from about 0.5 nm to about 100 nm (e.g., about 5 nm to 100 nm, as well as other thickness described herein). The film can include an optional underlayer or an optional surface activation step prior to deposition of the metal-containing precursor.

The film can have a vertical gradient that is characterized by a vertical change in EUV absorbance. In some instances, an increase in EUV absorbance along a depth (e.g., going from a top surface of the film towards the substrate) can correspond with an increase in metal content or halogen content along that same depth through the film layer. Non-limiting gradients include a linear gradient, an exponential gradient, a sigmoidal gradient, and the like. In particular embodiments, gradient density films of EUV-responsive moieties can yield more homogeneous film properties of EUV exposed areas at all depths in the film, which might improve development processes, improve EUV sensitivity, and/or improve patterning quality (e.g., having improved line-width-roughness (LWR) and/or line-edge-roughness (LER)).

The resist film can include an organometallic material, such as an organometal oxide (e.g., RM(MO)ₙ, in which M is a metal and R is a halogenated organic moiety having one or more carbon atoms and one or more halogen atoms). The substrate can include any useful wafer, feature(s), layer(s), or device(s). In some embodiments, substrates are silicon wafers having any useful feature (e.g., irregular surface topography), layer (e.g., photoresist layer), or device.

The radiation-sensitive film can include metal constituents and organic substituents, each of which may include UV-, DUV-, or EUV-sensitive moieties. Non-limiting examples of these include, e.g., a metal or a metalloid or an atom with a high EUV absorption cross-section, such as equal to or greater than 1×10⁷ cm²/mol. In other embodiments, the constituent includes or is M (e.g., in which M can be tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), lead (Pb), Xe, or a combination thereof). In some embodiments, the constituent includes a metal-containing precursor, a ligand-containing precursor, or a reaction product thereof.

The film can be homogenous. In particular embodiments, the homogenized matrix can be an alloy film. Co-deposition can occur in any useful methodology that uses co-flow of both the metal- and ligand-containing precursors (e.g., CVD).

The resulting film can be used as a photoresist. In particular non-limiting embodiments, the layer can include moieties that promote radiation absorption after radiation exposure (e.g., exposure to UV, DUV, and/or EUV radiation). In further embodiments, the organometallic layer can include metal centers and halogen atoms that promote radiation absorption. After deposition, the film can be patterned by radiation exposure and then developed, thereby providing a negative tone or positive tone resist. Such methods can include any useful lithography processes, deposition processes, EUV exposure processes, development processes, and post-application processes, as described herein. In particular embodiments, the film exhibits minimal film shrinkage after EUV exposure, development, and/or post-application processes.

Turning back to FIG. 1, further steps can include patterning the film by an EUV exposure 102 to provide an exposed film having EUV exposed areas 112b and EUV unexposed areas 112c. Patterning can include use of a mask 114 having EUV transparent regions and EUV opaque regions, in which EUV beams 115 are transmitted through the EUV transparent region and into the film 112. EUV exposure can include, e.g., an exposure having a wavelength in the range of about 10 nm to about 20 nm in a vacuum ambient (e.g., about 13.5 nm in a vacuum ambient).

The method 100 can further include developing 103 the film, thereby either (i) removing the EUV exposed areas to provide a pattern within a positive tone resist film or (ii) removing the EUV unexposed areas to provide a pattern within a negative tone resist. Path (i) in FIG. 1 results in selectively removing the EUV exposed areas 112b. Alternatively, path (ii) in FIG. 1 results in maintaining the EUV exposed areas 112b after development.

Developing steps can include use of halide chemistry (e.g., HBr chemistry) in a gas phase or use of aqueous or organic solvents in a liquid phase (e.g., as described herein). Developing steps can include any useful experimental conditions, such as a low pressure condition (e.g., of from about 1-100 mTorr), a plasma exposure (e.g., in the presence of vacuum), and/or a thermal condition (e.g., of from about −10-100° C.) that may be combined with any useful chemistry (e.g., halide chemistry or aqueous chemistry). Development can include, e.g., a halide-based etchant, such as HCl, HBr, H₂, Cl₂, Br₂, BCl₃, or combinations thereof, as well as any halide-based development process described herein; an aqueous alkali development solution; or an organic development solution. Additional development process conditions are described herein.

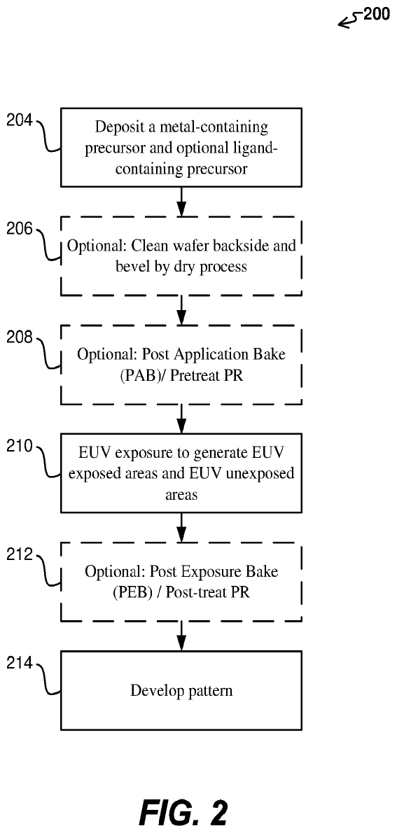

Optional steps may be conducted to further modulate, modify, or treat the EUV-sensitive film(s), substrate, photoresist layer(s), and/or in any method herein. FIG. 2 provides a flow chart of an exemplary method 200 having various operations, including optional operations. As can be seen, in operation 204, a metal-containing precursor and an optional ligand-containing precursor can be provided in the optional presence of a counter-reactant to provide a resist film (e.g., within a chamber).

In one instance, the method can include an optional step 206 of cleaning the backside surface or bevel of the substrate or removing an edge bead of the photoresist that was deposited in the prior step. Such cleaning or removing steps can be useful for removing particles that may be present after depositing a film layer. The removing step can include processing the wafer with a wet metal oxide (MeOx) edge bead removal (EBR) step.

In another instance, the method can include an optional step 208 of performing a post application bake (PAB) of the deposited photoresist layer, thereby removing residual moisture from the layer to form a film; or pretreating the photoresist layer in any useful manner. The optional PAB can occur after film deposition and prior to EUV exposure; and the PAB can involve a combination of thermal treatment, chemical exposure, and moisture to increase the EUV sensitivity of the film, thereby reducing the EUV dose to develop a pattern in the film.

In particular embodiments, the PAB step is conducted at a temperature greater than about 100° C. or at a temperature of from about 100-200° C. or 100-250° C. In some instances, a PAB is not performed within the method.

In operation 210, the film is exposed to EUV radiation to develop a pattern. Generally, the EUV exposure causes a change in the chemical composition of the film, creating a contrast in etch selectivity that can be used to remove a portion of the film. Such a contrast can provide a positive tone resist or a negative tone resist, as described herein.

In yet another instance, the method can include an optional step 212 of performing a post exposure bake (PEB) of the exposed film, thereby further removing residual moisture or promoting chemical condensation within the film; or post-treating the film in any useful manner. In another instance, the method can include (e.g., after development) hardening the patterned film, thereby providing a resist mask disposed on a top surface of the substrate. Hardening steps can include any useful process to further crosslink or react the EUV unexposed or exposed areas, such as steps of exposing to plasma (e.g., O₂, Ar, He, or CO₂ plasma), exposing to ultraviolet radiation, annealing (e.g., at a temperature of about 180-240° C.), thermal baking, or combinations thereof that can be useful for a post development baking (PDB) step. Additional post-application processes are described herein and may be conducted as an optional step for any method described herein.

Then, in operation 214, the photoresist (PR) pattern is developed. In various embodiments of development, the exposed regions are removed (positive tone) or the unexposed regions are removed (negative tone). In various embodiments, these steps may be dry processes and/or wet processes.

In some embodiments, the process includes all dry processes, including dry deposition of the film (e.g., with precursors in vapor form and a counter-reactant that includes water vapor) and dry development of the exposed film. Without wishing to be limited by mechanism, such films can provide a negative tone resist, in which radiation exposed regions provide a non-volatile material and radiation unexposed regions provide a volatile byproduct upon exposure to dry development chemistry (e.g., vapor-based etchant chemistry, such as any described herein). In this way, etchants in the vapor phase can be used to react with the unexposed film to provide volatile byproducts, which can also be removed by in its vapor form.

In other embodiments, a wet process can be employed in one or more operations. Such processes can include dry deposition of the film (e.g., with precursors in vapor form and a counter-reactant that includes water vapor) and wet development of the exposed film (e.g., using any wet developer described herein); as well as wet deposition of the film (e.g., with precursor in a solvent) and dry development of the exposed film; and wet deposition of the film with wet development of the exposed film. Without wishing to be limited by mechanism, such films can provide a positive tone resist, in which radiation exposed regions provide a material (e.g., including metal halide bonds, such as tin halide) that can be dissolved in a solvent and radiation regions provide a material that is more resistant to solvent dissolution.

Any useful type of chemistry can be employed during the depositing, patterning, and/or developing steps. Such steps may be based on dry processes employing chemistry in a gaseous phase or wet processes employing chemistry in a wet phase. Various embodiments include combining all dry operations of film formation by vapor deposition, (EUV) lithographic photopatterning, dry stripping, and dry development. Various other embodiments include dry processing operations described herein advantageously combined with wet processing operations, for example, spin-on EUV photoresists (wet process), such as available from Inpria Corp., may be combined with dry development or other wet or dry processes as described herein. In various embodiments, the wafer clean may be a wet process as described herein, while other processes are dry processes. In yet other embodiments, a wet development process may be used.

Without limiting the mechanism, function, or utility of the present technology, dry processes of the present technology may provide various benefits relative to wet development processes among those known in the art. For example, dry vapor deposition techniques described herein can be used to deposit thinner and more defect free films than can be applied using spin-coating techniques, in which the exact thickness of the deposited film can be modulated and controlled simply by increasing or decreasing the length of the deposition step or sequence. Accordingly, a dry process may provide more tunability and give further critical dimension (CD) control and scum removal. Dry development can improve performance (e.g., prevent line collapse due to surface tension in wet development) and/or enhance throughput (e.g., by avoiding wet development track). Other advantages may include eliminating the use of organic solvent developers, reducing sensitivity to adhesion issues, avoiding the need to apply and remove wet resist formulations (e.g., avoiding scumming and pattern distortion), improving line edge roughness, patterning directly over device topography, offering the ability to tune hardmask chemistry to the specific substrate and semiconductor device design, and avoiding other solubility-based limitations. Additional details, materials, processes, steps, and apparatuses are described herein.

### Descum/Smoothing/Curing

In some instances, there may be scum (material in the open portions of the unexposed, for example, regions of the EUV resist after development, most likely with high metal concentrations, like clusters), or roughness (the same composition, but on the sidewalls of the etched features in the developed pattern). These can be removed in a descum/smoothing operation by a He (or other inert gas) plasma desorption operation. Suitable process conditions for a such dry descum/smoothing operation may be: reactant flow of 100-500 scccm (e.g., 500 sccm He), temperature of −10 to 120° C. (e.g., −10° C.), pressure of 5-20 mT (e.g., 10 mT), plasma power of 100 to 300 W (e.g., 300 W) at high frequency (e.g., 13.56 MHz), wafer bias of 50 to 300 V_{b} and for a time of about 1 to 3 sec (e.g., 2 sec).

The He desorption, descum and cleaning of the unexposed resist residue can have the collateral benefit of curing the exposed resist to harden it thereby enhancing its hard mask function in subsequent operations to etch the underlying substrate. This resist hardening is achieved by exposure of the EUV exposed resist to UV radiation generated by the He plasma, which may be continued after the descum/smoothing is complete with the bias turned off. The He plasma curing may alternatively be performed if no descum/smoothing is needed or performed.

In some embodiments, the He plasma descum/smoothing may be cycled with dry development, as described above, for enhanced results. In this way, most of the organic component of the unexposed, for example, region of the pattern is removed by the dry development, then a short He plasma operation can remove some of the concentrated metal at the surface, opening up access to the remaining underlying organic material, that can then be removed in a subsequent dry development operation/cycle. Another cycle of He plasma may be used to remove any remaining metal to leave a clean and smooth feature surface. The cycling can be continued until all or substantially all the scum and roughness residue is removed to leave a clean and smooth feature surface.

This He desorption descum and smoothing is further illustrated with reference to an organotin oxide-based EUV photoresist that is dry developed with a HBr chemistry as described herein. Following an initial HBr development operation, a SnOx residue remains on the substrate surface underlying the EUV photoresist in the unexposed region. He desorption is able to remove the brominated SnOx surface layer of the residue, exposing more highly concentrated organic material of the residue. A second cycle of HBr dry development can then remove additional residue. The cycling can be continued, as needed.

U.S. Provisional Patent Application Ser. No. 63/203,507 filed Jul. 26, 2021 and entitled “Multistep Post Exposure Treatment to Improve Dry Development Performance of Metal Containing Resist”; U.S. Provisional Patent Application Ser. No. 62/705,616, filed Jul. 20, 2020 and entitled “Integrated Dry Processes for Patterning Radiation Photoresist Patterning”; U.S. Provisional Patent Application Ser. No. 63/364,180,507 filed May 4, 2022 and entitled “Post-Development Treatment of Metal-Containing Photoresist”; and U.S. Provisional Patent Application Ser. No. 63/200,921 filed Apr. 2, 2021 and entitled “Control of Metallic Contamination from Metal-Containing Photoresist” are all incorporated herein by reference.

### Metal-Containing Precursors

The metal-containing precursor can have any useful number and type of cleavable group(s) and/or ligand(s). A cleavable group (L) can be characterized by its ability to react in the presence of patterning radiation, and a ligand can be characterized by its ability to react in the presence of a counter-reactant. For instance, the metal-containing precursor can include a cleavable group that eliminates in the presence of patterning radiation. Such a group can include a C₁₋₄ (halo)aliphatic group. In another instance, the metal-containing precursor can include a ligand (e.g., dialkylamino groups or alkoxy groups) that reacts with a counter-reactant, which can introduce linkages between metal centers (e.g., an —O— linkage).

The metal-containing precursor can be, e.g., an organometallic agent, a metal halide, or a capping agent (e.g., as described herein).

In some embodiments, the metal is characterized by a high patterning radiation absorption cross-section (e.g., an EUV absorption cross-section that is equal to or greater than 1×10⁷ cm²/mol).

In some embodiments, the metal-containing precursor has at least one optionally substituted haloalkyl group. Non-limiting haloaliphatic groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH₂F), 2-chloroethyl (—CH₂CH₂C₁), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₋₄ haloalkyl, C₂₋₄ haloalkenyl, and C₂₋₄ haloalkynyl.

In other embodiments, the metal-containing precursor has at least one optionally substituted alkyl group, optionally substituted alkenyl, or optionally substituted alkynyl. Non-limiting groups include —CₙH₂ₙ₊₁, in which n is 1 or 2; —CₙH₂ₙ₋₁, in which n is 2, 3, or 4; or —CₙH₂ₙ₋₃, in which n is 2, 3, or 4. Yet other non-limiting groups include methyl (—CH₃), ethyl (—CH₂CH₃), vinyl or ethenyl (—CH═CH₂), 1-propenyl (—CH═CHCH₃), allyl or 2-propenyl (—CH₂—CH═CH₂), 1-butenyl (—CH═CHCH₂CH₃), 2-butenyl (—CH₂CH═CHCH₃), 3-butenyl (e.g. —CH₂CH₂CH═CH₂), ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), 2-methyl-1-propenyl (CH═C(CH₃)₂, isopropenyl (C(CH₃)═CH₂, 1-methylallyl (CH(CH₃)CH═CH₂ and the like.

In some embodiments, when the precursor is of the formula M(R¹)₄ or M(R⁶)₄, and M is tin, the precursor composition will contain less than about 0.5% of a di-aliphatic metal containing contaminant when two R¹s or two R⁶'s are the same aliphatic groups. In some embodiments, when the precursor is of the formula M(R¹)₄ or M(R⁶)₄, and M is tin, the precursor composition will contain less than about 0.1% of a di-aliphatic metal containing contaminant when two R¹s or two R⁶'s are the same aliphatic groups.

It has been observed that when films of the desired tin containing layers are deposited on multiple wafers and stored in a foop where multiple wafers are stored in the same container with the wafers positioned above one another with a small gap between them the as-deposited films can outgas material which can contaminate the underside of the wafer above it. This contamination can be transferred to wafer handling devices in other areas of the manufacturing facility, thus high levels of contamination is undesirable. In order to measure the levels of outgassing films are deposited onto a wafer and stored in a foop with a witness wafer in the slot above it turned upside down with the clean/polished surface facing the test wafer. After several days the witness wafer is removed and the levels of tin which has outgassed onto the witness wafer is measured by vapor phase decomposition inductively coupled plasma mass spectroscopy (VPD-ICP-MS). For films deposited from isopropyl tris(dimethylamino)tin the level of outgassing can be correlated to the levels of di-isopropyl bis(dimethylamino)tin in the precursor used. After 20 days it was observed that films deposited from isopropyl tris(dimethylamino)tin with >0.5% di-isopropyl bis(dimethylamino)tin showed a tin surface concentration of 1E10 atoms/cm² while films deposited from isopropyl tris(dimethylamino)tin with <0.1% di-isopropyl bis(dimethylamino)tin showed a tin surface concentration of <0.1E10 atoms/cm².

In some embodiments, each ligand within the metal-containing precursor can be one that is reactive with a counter-reactant and/or a ligand-containing precursor.

For any formula herein, the metal can be a metal with a high patterning radiation absorption cross-section (e.g., an EUV absorption cross-section that is equal to or greater than 1×10⁷ cm²/mol). In some embodiments, M is tin (Sn), tellurium (Te), bismuth (Bi), antimony (Sb), hafnium (Hf), or zirconium (Zr). In further embodiments, M is Sn, a is 1, and b+c is 4. In other embodiments, M is Sn, a is 1, and b+c is 2. In yet other embodiments, M is Sn, a is 1, and c is 2. In particular embodiments, M is Sn(II), thereby providing a metal-containing precursor that is a Sn(II)-based compound. In other embodiments, M is Sn(IV), thereby providing a metal-containing precursor that is a Sn(IV)-based compound.

For any formula herein, each L is, independently, H, halo, azido, cyano, alkylcarbonyl, isothiocyanato, thiocyanato, optionally substituted alkyl, optionally substituted aryl, optionally substituted amino, optionally substituted bis(trialkylsilyl)amino, optionally substituted trialkylsilyl, or optionally substituted alkoxy (e.g., —OR¹, in which R¹ can be alkyl). In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, alkyl. In yet other embodiments, the optionally substituted trialkylsilyl is —SiR¹R²R³, in which each R¹, R², and R³ is, independently, alkyl.

In other embodiments, the formula includes a first L that is —NR¹R² and a second L that is —NR¹R², in which each R¹ and R² is, independently, H or alkyl; or in which R¹ from a first L and R¹ from a second L, taken together with the nitrogen atom and the metal atom to which each are attached, form a heterocyclyl group, as defined herein. In yet other embodiments, the formula includes a first L that is —OR¹ and a second L that is —OR¹, in which each R¹ is, independently, H or alkyl; or in which R¹ from a first L and R¹ from a second L, taken together with the oxygen atom and the metal atom to which each are attached, form a heterocyclyl group, as defined herein.

In some embodiments, at least one of L or R is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, L or R has at least one beta-hydrogen or beta-halogen.

In some embodiments, at least one of L or R is optionally substituted haloalkyl. Non-limiting haloalkyl groups include, e.g., CₙH_{2n+1-z}X_{z}, wherein n is 1, 2, 3, or greater; wherein z is 1 to 2n+1 (e.g., 1 to 3, 1 to 5, or 1 to 7); and wherein each X is, independently, halo (F, Cl, Br, or I). In various embodiments, L or R has at least one beta-hydrogen and/or beta-halogen. In particular, the metal-containing precursor can be FCH₂SnL₃, CF₃SnL₃, ICH₂SnL₃, CI₃SnL₃, CH₂FCH₂SnL₃, or CH₂ICH₂SnL₃, in which each L can be any described herein (e.g., including halo, optionally substituted amino, or optionally substituted alkoxy).

In some embodiments, at least one of L or R is optionally substituted alkenyl or optionally substituted alkynyl. Non-limiting alkenyl groups include, e.g., CₙH₂ₙ₋₁, where n is 2, 3, 4, or greater, such as ethenyl, 1-propenyl, 2-propenyl, 1-butenyl, 2-butenyl, or 3-butenyl. Non-limiting alkynyl groups include, e.g., CₙH₂ₙ₋₃, where n is 2, 3, 4, or greater, such as ethynyl, 1-propynyl, 2-propynyl, 1-butynyl, 2-butynyl, or 3-butynyl.

There are several types of alkynyl tin precursors for use in dry resist. These precursors can react in different ways depending on where the carbon-carbon triple bond is located. If the carbon-carbon triple bond is not bound directly to the tin center, for example in a formula R¹CCCH₂SnL₃ where R¹ is a C₁-C₂ linear or branched alkane such as methyl or ethyl; and L is an amino (dimethylamino, diethylamino, ethylmethylamino, methylpropylamino, aminiocyclopentane, aminocyclohexane) or alkoxy group (methoxy, ethoxy, n-propoxy, isopropoxy, t-butoxy, sec-butoxy, or n-butoxy). In this type of precursor, the unsaturated triple bond will be incorporated into the film and is expected to crosslink with other unsaturated groups.

Alkyne compounds which have a carbon-carbon triple bond directly bonded to the tin atom will hydrolyze in the presence of water similar to, although much slower than, amino and alkoxy groups. Therefore, compounds such as (R¹C≡C)₃SnR² and (R¹C≡C)₄Sn where R¹ is a simple alkane such as methyl or ethyl, and R² is a C₁-C₂ hydrocarbon are another method of introducing alkyl and groups into a tin-oxo compounds. In compound (R¹C≡C)₃SnR² the tin center has three alkynes with the carbon-carbon triple bond bonded to the tin center. These precursors will react in a mechanism similar to the previously described amino or alkoxy tin compounds although the alkyne precursors may be more stable thermally or hydrolytically than the alkoxy or amino compounds. Due to the slow hydrolysis of the alkyne compounds it may be possible to use tetra-alkynes such as those shown for (R¹C≡C)₄Sn. Using (R¹C≡C)₄Sn it may be possible by controlling the water to precursor ratio to deposit films which contain a tin oxo network while still maintaining some amount of alkyne groups in the film which can crosslink.

In some embodiments, each L or at least one L is halo. In particular, the metal-containing precursor can be a metal halide or organometal halide. Non-limiting metal halides and organometal halides include FCH₂SnX₃, CF₃SnX₃, ICH₂SnX₃, CI₃SnX₃, CH₂FCH₂SnX₃, CH₂ICH₂SnX₃, SnX₂, or SnX₄, in which each X is, independently, halo. In other embodiments, the metal-containing precursor is RSnX₃, in which R is C₁₋₄ haloalkyl, C₂₋₄ haloalkenyl, or C₂₋₄ haloalkynyl; and in which each X is, independently, halo. In yet other embodiments, the metal-containing precursor is RSnX₃, in which R is C₁₋₂ alkyl, C₂₋₄ alkenyl, or C₂₋₄ alkynyl; and in which each X is, independently, halo.

In some embodiments, each L or at least one L can include a nitrogen atom. In particular embodiments, one or more L can be optionally substituted amino or optionally substituted bis(trialkylsilyl)amino. Non-limiting L substituents can include, e.g., —NMe₂, —NEt₂, —NMeEt, —N(t-Bu)-[CHCH₃]₂—N(t-Bu)-(tbba), —N(SiMe₃)₂, and —N(SiEt₃)₂. Non-limiting metal-containing precursors can include, e.g., Sn(CH₂F)(NMe₂)₃, Sn(CF₃)(NMe₂)₃, Sn(CH₂I)(NMe₂)₃, Sn(Cl₃)(NMe₂)₃, Sn(CH₂CH₂F)(NMe₂)₃, Sn(CH₂CH₂I)(NMe₂)₃, Sn(CH₂F)₂(NMe₂)₂, Sn(CF₃)₂(NMe₂)₂, Sn(CH₂I)₂(NMe₂)₂, Sn(CI₃)₂(NMe₂)₂, Sn(CH₂CH₂F)₂(NMe₂)₂, Sn(CH₂CH₂I)₂(NMe₂)₂, Sn(CH₂F)(NEt₂)₃, Sn(CF₃)(NEt₂)₃, Sn(CH₂I)(NEt₂)₃, Sn(CI₃)(NEt₂)₃, Sn(CH₂CH₂F)(NEt₂)₃, Sn(CH₂CH₂I)(NEt₂)₃, Sn(CH₃)(NMe₂)₃, Sn(CH₂CH₃)(NMe₂)₃, Sn(CH═CH₂)(NMe₂)₃, Sn(CH═CHCH₃)(NMe₂)₃, Sn(CH₂—CH═CH₂)(NMe₂)₃, Sn(C≡CH)(NMe₂)₃, Sn(C≡CCH₃)(NMe₂)₃, Sn(CH₂C≡CH)(NMe₂)₃, Sn(NMe₂)₂, Sn(NEt₂)₂, or Sn[N(SiMe₃)₂]₂.

In some embodiments, the metal-containing precursor is RSn(NMe₂)₃, RSn(NMe₂)₂(NEt₂), RSn(NEt₂)₃, or RSn[N(SiMe₃)₂]₃, in which R is C₁₋₂ haloalkyl, C₂₋₄ haloalkenyl, C₂₋₄ haloalkynyl, C₁₋₂ alkyl, C₂₋₄ alkenyl, or C₂₋₄ alkynyl. In other embodiments, the metal-containing precursor is R₂Sn(NMe₂)₂, R₂Sn(NMe₂)(NEt₂), R₂Sn(NEt₂)₂, or R₂Sn[N(SiMe₃)₂]₂, in which each R is, independently, C₁₋₂ haloalkyl, C₂₋₄ haloalkenyl, C₂₋₄ haloalkynyl, C₁₋₂ alkyl, C₂₋₄ alkenyl, or C₂₋₄ alkynyl.

In other embodiments, the metal-containing precursor is RSnL₃, in which R is C₁₋₂ haloalkyl, C₂₋₄ haloalkenyl, C₂₋₄ haloalkynyl, C₁₋₂ alkyl, C₂₋₄ alkenyl, or C₂₋₄ alkynyl; and in which each L is, independently, selected from the group of —NMe₂, —NEt₂, —NMeEt, —N(t-Bu)-[CHCH₃]₂—N(t-Bu)-(tbba), —N(SiMe₃)₂, and —N(SiEt₃)₂.

In other embodiments, the metal-containing precursor is RSnL₃, in which R is C₁-C₃ aliphatic (wherein the C₁-C₃ aliphatic may be optionally substituted with a ketone, an alkoxy group, an epoxy group) or a —C(O)C₁-C₃ alkyl group; and in which each L is, independently, selected from the group of optionally substituted alkoxy, —NMe₂, —NEt₂, —NMeEt, —N(t-Bu)-[CHCH₃]₂—N(t-Bu)-(tbba), —N(SiMe₃)₂, and —N(SiEt₃)₂. Ethers, ketones or epoxide-containing R groups on the metal-containing precursors may be advantageous to assist in crosslinking.

In yet other embodiments, the metal-containing precursor is SnL₂, in which each L is, independently, selected from the group of —NMe₂, —NEt₂, —NMeEt, —N(t-Bu)-[CHCH₃]₂—N(t-Bu)-(tbba), —N(SiMe₃)₂, and —N(SiEt₃)₂.

In some embodiments, each L or at least one L can include a silicon atom. In particular embodiments, one or more L can be optionally substituted trialkylsilyl or optionally substituted bis(trialkylsilyl)amino. Non-limiting L substituents can include, e.g., —SiMe₃, —SiEt₃, —N(SiMe₃)₂, and —N(SiEt₃)₂. Non-limiting metal-containing precursors can include, e.g., Sn[N(SiMe₃)₂]₂, bis(trimethylsilyl)tellurium (Te(SiMe₃)₂), bis(triethylsilyl)tellurium (Te(SiEt₃)₂), or Bi[N(SiMe₃)₂]₃.

In some embodiments, each L or at least one L can include an oxygen atom. In particular embodiments, one or more L can be optionally substituted alkoxy. Non-limiting L substituents include, e.g., methoxy, ethoxy, isopropoxy (i-PrO), t-butoxy (t-BuO), and —O═C(CH₃)—CH═C(CH₃)—O— (acac). Non-limiting metal-containing precursors include, e.g., Sn(CH₂F)(t-BuO)₃, Sn(CF₃)(t-BuO)₃, Sn(CH₂I)(t-BuO)₃, Sn(CI₃)(t-BuO)₃, Sn(CH₂CH₂F)(t-BuO)₃, Sn(CH₂CH₂I)(t-BuO)₃, Sn(CH₂F)₂(t-BuO)₂, Sn(CF₃)₂(t-BuO)₂, Sn(CH₂I)₂(t-BuO)₂, Sn(CI₃)₂(t-BuO)₂, Sn(CH₂CH₂F)₂(t-BuO)₂, Sn(CH₂CH₂I)₂(t-BuO)₂, Sn(t-BuO)₂, Sn(CH₃)(t-BuO)₃, Sn(CH₂CH₃)(t-BuO)₃, Sn(CH═CH₂)(t-BuO)₃, Sn(CH═CHCH₃)(t-BuO)₃, Sn(CH₂—CH═CH₂)(t-BuO)₃, Sn(C≡CH)(t-BuO)₃, Sn(C≡CCH₃)(t-BuO)₃, Sn(CH₂C≡CH)(t-BuO)₃, or Sn(acac)₂.

In some embodiments, the metal-containing precursor is RSn(t-BuO)₃, in which R is C₁₋₂ haloalkyl, C₂₋₄ haloalkenyl, C₂₋₄ haloalkynyl, C₁₋₂ alkyl, C₂₋₄ alkenyl, or C₂₋₄ alkynyl. In other embodiments, the metal-containing precursor is R₂Sn(t-BuO)₂, in which each R is, independently, C₁₋₂ haloalkyl, C₂₋₄ haloalkenyl, C₂₋₄ haloalkynyl, C₁₋₂ alkyl, C₂₋₄ alkenyl, or C₂₋₄ alkynyl. In yet other embodiments, the metal-containing precursor is RSnL₃, in which R is C₁₋₂ haloalkyl, C₂₋₄ haloalkenyl, C₂₋₄ haloalkynyl, C₁₋₂ alkyl, C₂₋₄ alkenyl, or C₂₋₄ alkynyl; and in which each L is, independently, selected from the group of methoxy, ethoxy, i-PrO, and t-BuO.

To provide a film in one non-limiting instance, a ligand-containing precursor can be employed to react with the metal-containing precursor or to replace a ligand of the metal-containing precursor. Non-limiting ligand-containing precursors are described herein.

Such precursor(s) can be further used in combination with one or more counter-reactants. Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as O₂, O₃, water, peroxides (e.g., hydrogen peroxide), oxygen plasma, water plasma, alcohols, di- or polyhydroxy alcohols, fluorinated di- or polyhydroxy alcohols, fluorinated glycols, formic acid, and other sources of hydroxyl moieties, as well as combinations thereof. In various embodiments, a counter-reactant reacts with the metal- and/or ligand-containing precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges.

In addition, hydrogen iodide may be utilized to incorporate iodine into the film.

In particular embodiments, the counter-reactant is a chalcogenide precursor, e.g., that includes a structure having formula: X³—Z—X⁴, wherein:
Z is sulfur, selenium, or tellurium; and
each of X³ and X⁴ is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

Using the metal-containing precursors herein, a gradient film can be formed. For instance, various atoms present in the metal-containing precursor, ligand-containing precursor, and/or counter-reactant can be provided within a gradient film. In some embodiments of the techniques discussed herein, a non-limiting strategy that can further improve the EUV sensitivity in a photoresist (PR) film is to create a film in which the film composition is vertically graded, resulting in depth-dependent EUV sensitivity. In a homogenous PR with a high absorption coefficient, the decreasing light intensity throughout the film depth necessitates a higher EUV dose to ensure the bottom is sufficiently exposed. By increasing the density of atoms with high EUV absorptivity at the bottom of the film relative to the top of the film (i.e., by creating a gradient with increasing EUV absorption), it becomes possible to more efficiently use available EUV photons while more uniformly distributing absorption (and the effects of secondary electrons) towards the bottom of more highly absorbing films. In one non-limiting instance, the gradient film includes Te, I, or other atoms towards the bottom of the film (e.g., closer to the substrate).

The strategy of engineering a vertical composition gradient in a PR film is particularly applicable to dry deposition methods, such as CVD and ALD, and can be realized by tuning the flow ratios between different reactants during deposition. The type of composition gradients that can be engineered include: the ratios between different high-absorbing metals, the percentage of metal atoms that have EUV-cleavable organic groups, the percentages of (halo)aliphatic substituents and/or counter-reactants that contain high-absorbing elements, and combinations of the above.

The composition gradient in the EUV PR film can also bring additional benefits. For instance, high density of high-EUV-absorbing elements in the bottom part of the film can effectively generate more secondary electrons that can better expose upper portions of the film. In addition, such compositional gradients can also be directly correlated with a higher fraction of EUV absorbing species that are not bonded to bulky, terminal substituents. For example, in the case of Sn-based resists, the incorporation of tin precursors with four leaving groups is possible, thereby promoting the formation of Sn—O-substrate bonding at the interface for improved adhesion.

Such gradient films can be formed by using any metal-containing precursors (e.g., tin or non-tin precursors), ligand-containing precursors, and/or counter-reactants, described herein. Yet other films, methods, precursors, and other compounds are described in U.S. Provisional Pat. Appl. No. 62/909,430, filed Oct. 2, 2019, and titled SUBSTRATE SURFACE MODIFICATION WITH HIGH EUV ABSORBERS FOR HIGH PERFORMANCE EUV PHOTORESISTS and International Appl. No. PCT/US20/70172, filed Jun. 24, 2020 and titled PHOTORESIST WITH MULTIPLE PATTERNING RADIATION-ABSORBING ELEMENTS AND/OR VERTICAL COMPOSITION GRADIENT, the disclosures of which at least relating to the composition, deposition, and patterning of directly photopatternable metal oxide films to form EUV resist masks are incorporated by reference herein.

Furthermore, two or more different precursors can be employed within each layer (e.g., a film or a capping layer). For instance, two or more of any metal-containing precursors herein can be employed to form an alloy. In one non-limiting instance, tin telluride can be formed by employing tin precursor including an —NR₂ ligand with RTeH, RTeD, or TeR₂ precursors, in which R is an alkyl, particularly t-butyl or i-propyl. In another instance, a metal telluride can be formed by using a first metal precursor including an alkoxy or a halo ligand (e.g., SbCl₃) with a tellurium-containing precursor including a trialkylsilyl ligand (e.g., bis(trimethylsilyl)tellurium).

Yet other exemplary EUV-sensitive materials, as well as processing methods and apparatuses, are described in U.S. Pat. No. 9,996,004 and Int. Pat. Pub. No. WO 2019/217749, each of which is incorporated herein by reference in its entirety.

### Ligand-Containing Precursors

The ligand-containing precursor can be any having a ligand (e.g., reactive with a counter-reactant and/or a metal-containing precursor). In one embodiment, such ligand-containing chemistries will generally be employed before the film deposition process to prepare to the appropriate metal-containing precursor.

In particular embodiments, the ligand-containing precursor is an organolithium compound (e.g., LiL), an organosodium compound (e.g., NaL), an organomagnesium compound (e.g., MgL₂), a Grignard reagent (e.g., MgLX, in which X is halo), an organozinc compound (e.g., ZnL₂), or an organoaluminum compound (e.g., AlL₃).

In another embodiment, the ligand-containing precursor can be employed to synthesize the precursor (prior to deposition) or to provide a precursor in situ (e.g., during deposition within the chamber). In some embodiments, the metal-containing precursor includes tin(II).

Other ligand-containing precursors can include organolithium compounds, such as lithium dimethylamide [LiNMe₂] and lithium bis(trimethylsilyl)amide [LiN(SiMe₃)₂].

Yet other ligand-containing precursors can include aluminum halides, such as aluminum bromide [AlBr₃] and aluminum chloride [AlCl₃]; organoaluminum, including trialkylaluminum and triarylaluminum, such as trimethylaluminum [AlMe₃] and triethylaluminum [AlEt₃]; aluminum alkoxides, such as aluminum methoxide [Al(OMe)₃] and aluminum i-propoxide [Al(OiPr)₃]; tris(dialkylamido)aluminum, such as tris(dimethylamido)aluminum [Al(NMe₂)₃ or Al₂(NMe₂)₆].

Yet other ligand-containing precursors can include haloalkyl halides or alkyl halides, such as haloalkyl iodide, haloalkyl bromide, haloalkyl chloride, haloalkyl fluoride, alkyl iodide, alkyl bromide, alkyl chloride, or alkyl fluoride. In some embodiments, the haloalkyl is —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; —CH₂CX_{y}H_{3-y}, wherein y is 1, 2, or 3, and wherein each X is, independently, halo (F, Cl, Br, or I); or CₙH_{2n+1-z}X_{z} wherein n is 1, 2, 3, or greater, wherein z is 1 to 2n+1 (e.g., 1 to 3, 1 to 5, or 1 to 7), and wherein each X is, independently, halo (F, Cl, Br, or I). Yet other non-limiting haloalkyl groups include halo-substituted methyl including one, two, or three halo substitutions and the like, as described herein); halo-substituted ethyl including one, two, or three halo substitutions; and O-halo-substituted ethyl including one, two, or three halo substitutions (e.g., as described herein). In other embodiments, the alkyl is —CₙH₂ₙ₊₁, wherein n is 1 or 2; —CₙH₂ₙ₋₁, wherein n is 2, 3, or 4; or —CₙH₂ₙ₋₃, wherein n is 2, 3, or 4.

### Further Precursors

As described herein, the films, layers, and methods herein can be employed with any useful precursor. The precursors below can be used as metal-containing precursors or ligand-containing precursors.

Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino] tin (Sn[N(SiMe₃)₂]₂).

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-Bu)(NMe₂)₃), i-propyl(tris)dimethylamino tin (Sn(i-Pr)(NMe₂)₃), n-propyl tris(diethylamino) tin (Sn(n-Pr)(NEt₂)₃), and analogous alkyl(tris)(t-butoxy) tin compounds, such as t-butyl tris(t-butoxy) tin (Sn(t-Bu)(t-BuO)₃). In some embodiments, the organometallic agents are partially fluorinated.

### Lithographic Processes

EUV lithography makes use of EUV resists, which may be polymer-based chemically amplified resists produced by liquid-based spin-on techniques or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a metal-containing precursor (e.g., any described herein) to form a metal oxide (e.g., a layer including a network of metal oxide bonds, which may include other non-metal and non-oxygen groups) film as the imaging/photoresist (PR) layer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers. To date, these resists have been developed using a wet (solvent) approach, which requires the wafer to move to the track, where it is exposed to developing solvent, dried and baked. Wet development does not only limit productivity but can also lead to line collapse due to surface tension effects during the evaporation of solvent between fine features.

Dry development techniques have been proposed to overcome these issues by eliminating substrate delamination and interface failures. Dry development has its own challenges, including etch selectivity between unexposed and EUV exposed resist material which can lead to a higher dose to size requirement for effective resist exposure when compared to wet development. Suboptimal selectivity can also cause PR corner rounding due to longer exposures under etching gas, which may increase line CD variation in the following transfer etch step. Additional processes employed during lithography are described in detail below.

### Deposition Processes, Including Dry Deposition

As discussed above, the present disclosure provides methods for making imaging layers on semiconductor substrates, which may be patterned using EUV or other next generation lithographic techniques. Methods include those where polymerized organometallic materials are produced in a vapor and deposited on a substrate. In some embodiments, dry deposition can employ any useful metal-containing precursor (e.g., metal halides, capping agents, or organometallic agents described herein). In other embodiments, a spin-on formulation may be used. Deposition processes can include applying a EUV-sensitive material as a resist film and/or as a capping layer upon the resist film. Exemplary EUV-sensitive materials are described herein.

The present technology includes methods by which EUV-sensitive films are deposited on a substrate, such films being operable as resists for subsequent EUV lithography and processing. Furthermore, a secondary EUV-sensitive film can be deposited upon an underlying primary EUV-sensitive film. In one instance, the secondary film constitutes a capping layer, and the primary film constitutes the imaging layer.

Such EUV-sensitive films comprise materials which, upon exposure to EUV, undergo changes, such as the loss of bulky pendant ligands bonded to metal atoms in low density M-OH rich materials, allowing their crosslinking to denser M-O-M bonded metal oxide materials. In other embodiments, EUV exposure results in further cross-linking between ligands bonded to metal atoms, thereby providing denser M-L-M bonded organometallic materials, in which L is a ligand. In yet other embodiments, EUV exposure results in loss of ligands to provide M-OH materials that can be removed by positive tone developers.

Through EUV patterning, areas of the film are created that have altered physical or chemical properties relative to unexposed areas. These properties may be exploited in subsequent processing, such as to dissolve either unexposed or exposed areas or to selectively deposit materials on either the exposed or unexposed areas. In some embodiments, the unexposed film has a hydrophobic surface, and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density, and cross-linking of the film. Removal may be by wet processing or dry processing, as further described herein.

The thickness of the EUV-patternable film formed on the surface of the substrate may vary according to the surface characteristics, materials used, and processing conditions. In various embodiments, the film thickness may range from about 0.5-100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10-20 nm. Without limiting the mechanism, function, or utility of the present disclosure, it is believed that, unlike wet, spin-coating processes of the art, the processes of the present disclosure have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

The film (e.g., imaging layer) or capping layer may be composed of a metal oxide layer deposited in any useful manner. Such a metal oxide layer can be deposited or applied by using any EUV-sensitive material described herein, such as a metal-containing precursor (e.g., a metal halide, a capping agent, or an organometallic agent) in combination with an optional ligand-containing precursor. In exemplary processes, a polymerized organometallic material is formed in vapor phase or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the capping layer.

Exemplary deposition techniques (e.g., for a film or a capping layer) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which metal-containing precursors, ligand-containing precursors, and counter-reactants are separated in either time or space.

A method for deposition of a tin based EUV resist is to react tetrakis(dimethylamino)tin in some embodiments with an acetamide in the gas phase. The acetamide reagents will replace the amine groups on the tin generating a tin complex Sn(NR′C(O)R)₄. In an embodiment, a central tin atom is 6-coordinate with two of the acetamide ligands being 2-coordinate and 2 being singly coordinated. Upon exposure to EUV radiation and secondary electrons the acetamide ligands may break apart to begin forming Sn—O—Sn bonds. R and R′ may each independently be H, C₁-C₇ linear, branched, or cyclic alkanes for example methyl, ethyl, isopropyl, n-propyl, n-butyl, sec-butyl, tert-butyl, cyclopentyl, cyclohexyl, phenyl, or benzyl. Useful acetamides include acetamide, N-methylacetamide, N-ethylacetamide, N-methylformamide, N-ethylformamide, N-methylproipamide, or propiomide.

Further description of precursors and methods for their deposition as EUV photoresist films applicable to this disclosure may be found in International Appl. No. PCT/US19/31618, published as International Pub. No. WO2019/217749, filed May 9, 2019, and titled METHODS FOR MAKING EUV PATTERNABLE HARD MASKS. The thin films may include optional materials in addition to a metal-containing precursor, a ligand-containing precursor, and a counter-reactant to modify the chemical or physical properties of the film, such as to modify the sensitivity of the film to EUV or enhancing etch resistance. Such optional materials may be introduced, such as by doping during vapor phase formation prior to deposition on the substrate, after deposition of the film, or both. In some embodiments, a gentle remote H₂ plasma may be introduced so as to replace some Sn-L bonds with Sn—H, for example, which can increase reactivity of the resist under EUV.

In general, methods can include mixing a vapor stream of an organometallic precursor (e.g., a metal-containing precursor, such as an organometallic agent) with an optional vapor stream of a ligand-containing precursor and an optional vapor stream of a counter-reactant so as to form a polymerized organometallic material, and depositing the organometallic material onto the surface of the semiconductor substrate. In some embodiments, mixing the metal-containing precursor with the optional ligand-containing precursor and optional counter-reactant can form a polymerized organometallic material. As will be understood by one of ordinary skill in the art, the mixing and depositing aspects of the process may be concurrent, in a substantially continuous process.

In an exemplary continuous CVD process, two or more gas streams, in separate inlet paths, of sources of metal-containing precursor, optional ligand-containing precursor, and optional counter-reactant are introduced to the deposition chamber of a CVD apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of metal-containing precursor, optional ligand-containing precursor, and optional counter-reactant are mixed in the chamber, allowing the metal-containing precursor, optional ligand-containing precursor, and optional counter-reactant to react to form a polymerized organometallic material or a film (e.g., a metal oxide coating or agglomerated polymeric materials, such as via metal-oxygen-metal bond formation).

For depositing metal oxide, the CVD process is generally conducted at reduced pressures, such as from 0.1-10 Torr. In some embodiments, the process is conducted at pressures from 1-2 Torr. The temperature of the substrate is preferably below the temperature of the reactant streams. For example, the substrate temperature may be from 0-250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5-2 Torr. The temperature of the substrate is preferably at or below the temperature of the reactant streams. For example, the substrate temperature may be from 0-250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by ligand-containing precursor and/or counter-reactants, and is then condensed or otherwise deposited onto the substrate.

A potential advantage of using dry deposition methods is ease of tuning the composition of the film as it grows. In a CVD process, this may be accomplished by changing the relative flows of the metal-containing precursor and the ligand-containing precursor during deposition. Deposition may occur between 30-200° C. at pressures between 0.01-100 Torr, but more generally between about 0.1-10 Torr.

A film (e.g., a metal oxide coating or agglomerated polymeric materials, such as via metal-oxygen-metal bond formation) may also be deposited by an ALD process. For example, the metal-containing precursor, optional ligand-containing precursor, and optional counter-reactant are introduced at separate times, representing an ALD cycle. The metal-containing precursor and optional ligand-containing precursor react on the surface, forming up to a monolayer of material at a time for each cycle. This may allow for excellent control over the uniformity of film thickness across the surface. The ALD process is generally conducted at reduced pressures, such as from 0.1-10 Torr. In some embodiments, the process is conducted from 1-2 Torr. The substrate temperature may be from 0-250° C., or from ambient temperature (e.g., 23° C.) to 150° C. The process may be a thermal process or, preferably, a plasma-assisted deposition.

Any of the deposition methods herein can be modified to allow for use of two or more different metal-containing precursors. In one embodiment, the precursors can include the same metal but different ligands. In another embodiment, the precursors can include different metal groups. In one non-limiting instance, alternating flows of various volatile metal-containing precursors can provide a mixed metal layer, such as use of a metal alkoxide precursor having a first metal (e.g., Sn) with a silyl-based precursor having a different second metal (e.g., Te).

Also, any of the deposition methods herein can be modified to allow for use of two or more different ligand-containing precursors. In one embodiment, the ligand-containing precursors can provide different bound ligands to the metal centers. In one non-limiting instance, alternating flows of various ligand-containing precursor can provide a layer with varying ligand content, such as in a gradient film.

Furthermore, any of the deposition methods herein can be modified to provide one or more layers within a film or a capping layer. In one instance, different metal-containing precursors and/or ligand-containing precursors can be employed in each layer. In another instance, the same precursor may be employed for each layer, but the top-most layer can possess a different chemical composition (e.g., a different density of metal-ligand bonds, a different metal to carbon ratio, a different halogen content, or a different bound ligand, as provided by modulating or changing the metal- or ligand-containing precursor).

Processes herein can be used to achieve a surface modification. In some iterations, a vapor of the metal-containing precursor may be passed over the wafer. The wafer may be heated to provide thermal energy for the reaction to proceed. In some iterations, the heating can be between about 50-250° C. In some cases, pulses of the metal- and/or ligand-containing precursor may be used, separated by pump and/or purging steps. In one instance, the ligand-containing precursor may be pulsed between the precursor pulses resulting in ALD or ALD-like growth. In other cases, both the metal- and ligand-containing precursors may be flowed at the same time. Examples of elements useful for surface modification include I, F, Sn, Bi, Sb, Te, and oxides or alloys of these compounds.

The processes herein can be used to deposit a thin metal oxide or metal by ALD or CVD. Examples include SnOx, BiOx, and Te. Following deposition, the film may be capped with a haloalkyl-substituted precursor or alkyl-substituted precursor of the form MₐR_{b}L_{c}, as described elsewhere herein. A counter-reactant may be used to better remove the ligands, and multiple cycles may be repeated to ensure complete saturation of the substrate surface. The surface can then ready for the EUV-sensitive film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited), on a film (e.g., upon which a capping layer is to be deposited), or on a capping layer.

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function, or utility of the present technology, it is believed that, in some embodiments, methods of the present technology offer advantages relative to methods among those known in the art in which photolithographic films are deposited on the surface of substrates using spin casting methods. Such advantages may derive from the conformance of the films of the present technology to underlying features without “filling in” or otherwise planarizing such features, and the ability to deposit films on a wide variety of material surfaces.

In some embodiments, an incoming wafer can be prepared with a substrate surface of a desired material, with the uppermost material being the layer into which the resist pattern is transferred. While the material selection may vary depending on integration, it is generally desired to select a material that can be etched with high selectivity to (i.e., much faster than) the EUV resist or imaging layer. Suitable substrate materials can include various carbon-based films (e.g., ashable hard mask (AHM)), silicon-based films (e.g., silicon, silicon oxide, silicon nitride, silicon oxynitride, or silicon oxycarbonitride, as well as doped forms thereof, including SiOₓ, SiOₓN_{y}, SiOₓC_{y}N_{z}, a-Si:H, poly-Si, or SiN), or any other (generally sacrificial) film applied to facilitate the patterning process.

In some embodiments, the substrate is a hard mask, which is used in lithographic etching of an underlying semiconductor material. The hard mask may comprise any of a variety of materials, including amorphous carbon (a-C), SnOₓ, SiO₂, SiOₓN_{y}, SiOₓC, Si₃N₄, TiO₂, TiN, W, W-doped C, WOₓ, HfO₂, ZrO₂, and Al₂O₃. For example, the substrate may preferably comprise SnOₓ, such as SnO₂. In various embodiments, the layer may be from 1-100 nm thick, or from 2-10 nm thick.

In some non-limiting embodiments, a substrate comprises an underlayer. An underlayer may be deposited on a hard mask or other layer and is generally underneath an imaging layer (or film), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In some embodiments, a surface activation operation may be used to activate the surface (e.g., of the substrate and/or a film) for future operations. For example, for a SiOₓ surface, a water or oxygen/hydrogen plasma may be used to create hydroxyl groups on the surface. For a carbon- or hydrocarbon-based surface, various treatment (e.g., a water, hydrogen/oxygen, CO₂ plasma, or ozone treatment) may be used to create carboxylic acids/or hydroxyl groups. Such approaches can prove critical for improving the adhesion of resist features to the substrate, which might otherwise delaminate or lift off during handling or within the solvent during development.

Adhesion may also be enhanced by inducing roughness in the surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed, in which a chemically reactive oxygen-containing plasma such as CO₂, O₂, or H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1-20 nm, or from 0.2-10 nm, or from 0.5-5 nm.

### EUV Exposure Processes

EUV exposure of the film can provide EUV exposed areas having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges. In other embodiments, EUV exposure provides cross-linked organic moieties by photopolymerizing ligands within the film; or EUV exposures releases gaseous by-products resulting from photolysis of bonds within a ligand.

EUV exposure can have a wavelength in the range of about 10-20 nm in a vacuum ambient, such as a wavelength of from 10-15 nm, e.g., 13.5 nm. In particular, patterning can provide EUV exposed areas and EUV unexposed areas to form a pattern.

The present technology can include patterning using EUV, as well as DUV or e-beam. In such patterning, the radiation is focused on one or more regions of the imaging layer. The exposure is typically performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hardmask (e.g., an ashable hardmask of PECVD amorphous hydrogenated carbon) is patterned using a conventional photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hardmask process and related vacuum-integrated hardware that combines film formation (deposition/condensation) and optical lithography with the result of greatly improved EUV lithography (EUVL) performance—e.g. reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10-20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to abeam of EUV light, typically under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Dry Development

EUV exposed or unexposed areas, as well as capping layers, can be removed by any useful development process. In one embodiment, the EUV exposed area can have activated reactive centers, such as dangling metal bonds, M-H groups, or dimerized M-M bonds. In particular embodiments, M-H groups can be selectively removed by employing one or more dry development processes (e.g., halide chemistry). In other embodiments, M-M bonds can be selectively removed by employing a wet development process, e.g., use of hot ethanol and water to provide soluble M(OH)˜groups. In yet other embodiments, EUV exposed areas are removed by use of wet development (e.g., by using a positive tone developer). In some embodiments, EUV unexposed areas are removed by use of dry development.

Dry development processes can also include use of halides, such as HCl- or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. The dry-deposited EUV photoresist films can be removed with etch rates of up to 1 nm/s. The quick removal of dry-deposited EUV photoresist films by these chemistries is applicable to chamber cleaning, backside clean, bevel clean, and PR developing. Although the films can be removed using vapors at various temperatures (e.g., HCl or HBr at a temperature greater than −10° C., or BCl₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1-100 mTorr), at a power level of <1000 W (e.g., <500 W). Temperatures may be from 30-300° C. (e.g., 30-120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100-500 W, with no bias. It should be understood that while these conditions are suitable for some processing reactors, e.g., a Kiyo etch tool available from Lam Research Corporation, Fremont, CA, a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon™). Such materials can be used in thermal processes of this disclosure without risk of removal by plasma exposure.

The process conditions for the dry development may be reactant flow of 100-500 sccm (e.g., 500 sccm HBr or HCl), temperature of −10-120° C. (e.g., −10° C.), pressure of 1-500 mTorr (e.g., 300 mTorr) with no plasma and for a time of about 10 sec to 1 min, dependent on the photoresist film and capping layer and their composition and properties.

In various embodiments, methods of the present disclosure combine all dry steps of film deposition, formation by vapor deposition, (EUV) lithographic photopatterning, and dry development. In such processes, a substrate may directly go to a dry development/etch chamber following photopatterning in an EUV scanner. Such processes may avoid material and productivity costs associated with a wet development. A dry process can also provide more tunability and give further CD control and/or scum removal.

In various embodiments, the EUV photoresist, containing some amount of metal, metal oxide and organic components, can be dry developed by a thermal, plasma (e.g., including possibly photoactivated plasma, such as lamp-heated or UV lamp heated), or a mixture of thermal and plasma methods while flowing a dry development gas including a compound of formula RxZy, where R=B, Al, Si, C, S, SO with x>0 and Z=Cl, H, Br, F, CH₄ and y>0. The dry development can result in a positive tone, in which the RxZy species selectively removes the exposed material, leaving behind the unexposed counterpart as a mask. In some embodiments, the exposed portions of organotin oxide-based photoresist films are removed by dry development in accordance with this disclosure. Positive tone dry development may be achieved by the selective dry development (removal) of EUV exposed regions exposed to flows comprising hydrogen halides or hydrogen and halides, including HCl and/or HBr without striking a plasma, or flows of H₂ and Cl₂ and/or Br₂ with a remote plasma or UV radiation generated from plasma to generate radicals.

Wet development methods can also be employed. In particular embodiments, such wet developments methods are used to remove EUV exposed regions to provide a positive tone photoresist or a negative tone resist. In some embodiments, wet development includes a neutral developer (e.g., a pH neutral developer, such as water) or a peroxide-containing developer (e.g., including hydrogen peroxide, H₂O₂). Exemplary, non-limiting wet development can include use of a base in an alkaline developer (e.g., an aqueous alkaline developer), such as those including ammonium, e.g., ammonium hydroxide (NH₄OH); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quaternary alkylammonium hydroxides; an organoamine, such as mono-, di-, and tri-organoamines (e.g., diethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, or R^{N1}R^{N2}R^{N3}R^{N4}N⁺X^{N1}, where each of R^{N1}, R^{N2}, R^{N3}, and R^{N4} is, independently, an organo substituent (e.g., optionally substituted alkyl or any described herein), or two or more organo substituents that can be joined together, and X^{N1} may comprise OH—, F—, Cl—, Br, I—, or other art-known quaternary ammonium cationic species. These bases may also comprise heterocyclyl nitrogen compounds known in the art, some of which are described herein. Non-limiting combinations include water with a basic developer.

Other development methodologies can include use of an acid in an acidic developer (e.g., an aqueous acidic developer or an acid developer in an organic solvent) that includes a halide (e.g., HCl or HBr), an organic acid (e.g., formic acid, acetic acid, or citric acid), or an organofluorine compound (e.g., trifluoroacetic acid); or use of an organic developer, such as a ketone (e.g., 2-heptanone, cyclohexanone, or acetone), an ester (e.g., γ-butyrolactone or ethyl 3-ethoxypropionate (EEP)), an alcohol (e.g., isopropyl alcohol (IPA)), or an ether, such as a glycol ether (e.g., propylene glycol methyl ether (PGME) or propylene glycol methyl ether acetate (PGMEA)), as well as combinations thereof. Non-limiting combinations include water with an acidic developer.

In particular embodiments, the positive tone developer is an aqueous alkaline developer (e.g., including NH₄OH, TMAH, TEAH, TPAH, or TBAH). In other embodiments, the negative tone developer is an aqueous acidic developer, an acidic developer in an organic solvent, or an organic developer (e.g., HCl, HBr, formic acid, trifluoroacetic acid, 2-heptanone, IPA, PGME, PGMEA, or combinations thereof).

Any of the developers herein can include one or more surfactants. Surfactant can include a positive, negative, or neutral charge and may be selected from the group consisting of fluorinated or non-fluorinated surfactants. Non-limiting surfactants include quaternary ammonium salts, perfluorooctanoic acid ammonium salt, perfluorononanoic acid ammonium salt, fluorosurfactants, polyoxyethylene stearylether, polyoxyethylene oleyl ether, polyoxyethylene octylphenyl ether, polyoxyethylene nonylphenyl ether, polyethylene glycol dilaurate, polyethylene glycol distearate, alkylbenzene sulfonates, sodium sulfosuccinate, and sodium lauryl sulfate.

Wet development can include any useful process, including immersion development, puddle development, and spray development. After or during any of these processes, the substrate can be rotated to remove dissolved portions of the film while simultaneously drying the film.

The development process can include both wet and dry development processes. Such a process can include an initial wet development followed by a later dry development, or vice versa. Development can also occur in cycles, in which a plurality of wet development processes are used, a plurality of dry development processes are used, or a plurality of wet and dry development processes are employed.

### Post-Application Processes

The methods herein can include any useful post-application processes, as described below.

For the backside and bevel clean process, the vapor and/or the plasma can be limited to a specific region of the wafer to ensure that only the backside and the bevel are removed, without any film degradation on the frontside of the wafer. The dry-deposited EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100-500 sccm (e.g., 500 sccm HCl, HBr, or H₂ and Cl₂ or Br₂, BCl₃ or H₂), temperature of −10-120° C. (e.g., 20° C.), pressure of 20-500 mTorr (e.g., 300 mTorr), plasma power of 0-500 W at high frequency (e.g., 13.56 MHz), and for a time of about 10-20 sec, dependent on the photoresist film and composition and properties. It should be understood that while these conditions are suitable for some processing reactors, e.g., a Kiyo etch tool available from Lam Research Corporation, Fremont, CA, a wider range of process conditions may be used according to the capabilities of the processing reactor.

Photolithography processes typically involve one or more bake steps, to facilitate the chemical reactions required to produce chemical contrast between exposed and unexposed areas of the photoresist. For high volume manufacturing (HVM), such bake steps are typically performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post treatments to metal and/or metal oxide-based photoresists after deposition (e.g., post-application bake (PAB)) and/or exposure (e.g., post-exposure bake (PEB)) and/or development (e.g., post-development bake (PDB)) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used.

In the case of post-application processing (e.g., PAB), a thermal process with control of temperature, gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., incubating or PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂.

In the case of post-development processing (e.g., post development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase dry development selectivity. This thermal or radical modification can increase the contrast between unexposed and exposed material and thus increase the selectivity of the subsequent dry development step. The resulting difference between the material properties of unexposed and exposed material can be tuned by adjusting process conditions including temperature, gas flow, moisture, pressure, and/or RF power. The large process latitude enabled by dry development, which is not limited by material solubility in a wet developer solvent, allows more aggressive conditions to be applied further enhancing the material contrast that can be achieved. The resulting high material contrast feeds back a wider process window for dry development and thus enables increased productivity, lower cost, and better defectivity performance.

A substantial limitation of wet-developed resist films is limited temperature bakes. Since wet development relies on material solubility, heating to or beyond 220° C., for example, can greatly increase the degree of cross-linking in both exposed and unexposed regions of a metal-containing PR film such that both become insoluble in the wet development solvents, so that the film can no longer by reliably wet developed. For dry-developed resist films, in which the etch rate difference (i.e., selectivity) between the exposed and unexposed regions of the PR is relied upon for removal of just the exposed or unexposed portion of the resist, the treatment temperature in a PAB, PEB, or PDB can be varied across a much broader window to tune and optimize the treatment process, for example from about 90-250° C., such as 90-190° C., for PAB, and about 170-250° C. or more, such as 190-240° C., for PEB and/or PDB. Decreasing etch rate and greater etch selectivity has been found to occur with higher treatment temperatures in the noted ranges.

In particular embodiments, the PAB, PEB, and/or PDB treatments may be conducted with gas ambient flow in the range of 100-10000 sccm, moisture content in the amount of a few percent up to 100% (e.g., 20-50%), at a pressure between atmospheric and vacuum, and for a duration of about 1-15 minutes, for example about 2 minutes.

These findings can be used to tune the treatment conditions to tailor or optimize processing for particular materials and circumstances. For example, the selectivity achieved for a given EUV dose with a 220-250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained than would be possible in a wet development context.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

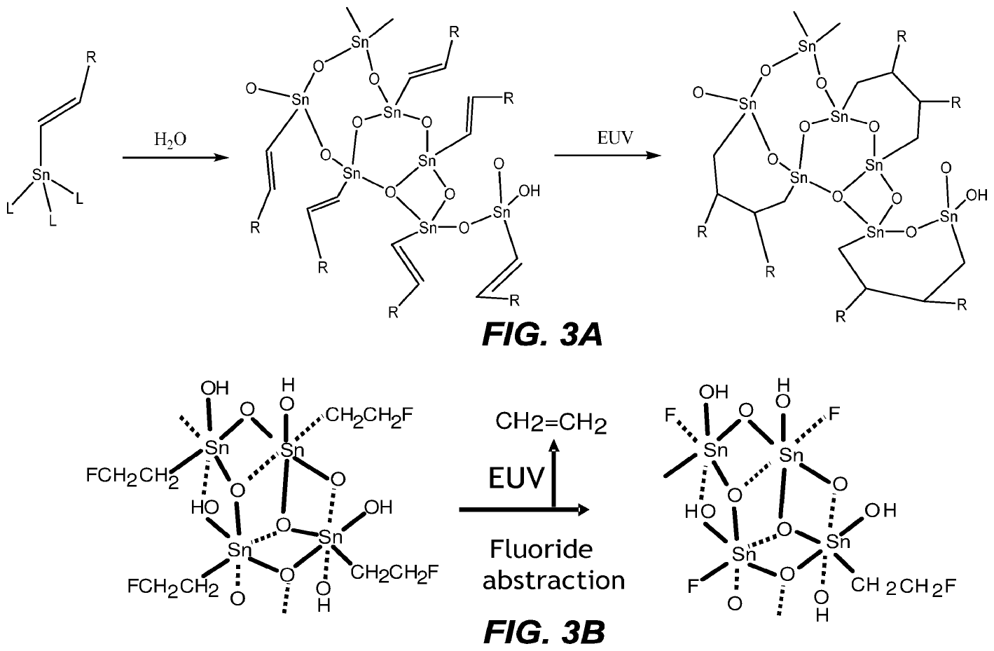

FIG. 3A schematically shows the formation of a tin-oxo network from an alkenyl substituent tin precursor upon reaction with water. Subsequent EUV exposure of the tin-oxo network results in reduction of some of the adjacent double bonds appended to tin to form carbon-carbon bonds. In some embodiments, dealkylation occurs. The presence of these bridging hydrocarbon groups provides a secondary hydrocarbon cross-linked network that results in films which are more resistant to etching, more sensitive and/or less subject to shrinkage during subsequent processing steps. The secondary hydrocarbon network may be a composite film including tin, oxygen and carbon in some embodiments. In some embodiments, the unsaturated groups react with the film to form a secondary carbon based network in addition to the tin-oxo network which may include carbon which forms bridges between two tin centers or may include carbon which forms non-volatile aliphatic chains.

FIG. 3B is a reaction scheme illustrating exposure of a tin-oxo network formed from a haloaliphatic-substituent containing tin precursor to EUV to form direct tin-halide bonds in accordance with certain disclosed embodiments. In some embodiments, dealkylation occurs. In some embodiments, active tin centers generated during EUV exposure will abstract a halide from the haloaliphatic substituent to form an Sn—X bond, which may enhance the differentiation of exposed to unexposed regions of the dry resist film.

Strategies for enhancing the EUV sensitivity and patterning performance of isopropyl(tris)dimethylamino tin based dry resist process involve the incorporation of carbon-fluorine (C—F) bonds into a thin interfacial layer applied directly under the resist and over an amorphous carbon hardmask. The introduction of C—F moieties can be accomplished using a wide range of precursor chemistries including some commonly employed for the plasma etching of silicon-based devices. While shallow incorporation of fluorine into amorphous carbon surfaces can be accomplished using a variety of inorganic precursors (including NF₃, SF₆, or even F₂ itself), approaches to useful lower density C—F rich interface layers employ partially fluorinated hydrocarbon precursors of composition CₙHₓF_{y} with x+y=2n+2. In addition to the available one and two carbon etch gases that fit the bill, related CnHxFy compositions (with x+y=2n) possessing either a Carbon-Carbon double bond or strained ring structures appear particularly well suited to deposition. However, some widely used per-fluorinated precursors such a tetrafluoroethylene or octafluorocyclobutane (at least without co-reactant give TEFLON-like surfaces poorly suited to resist application.

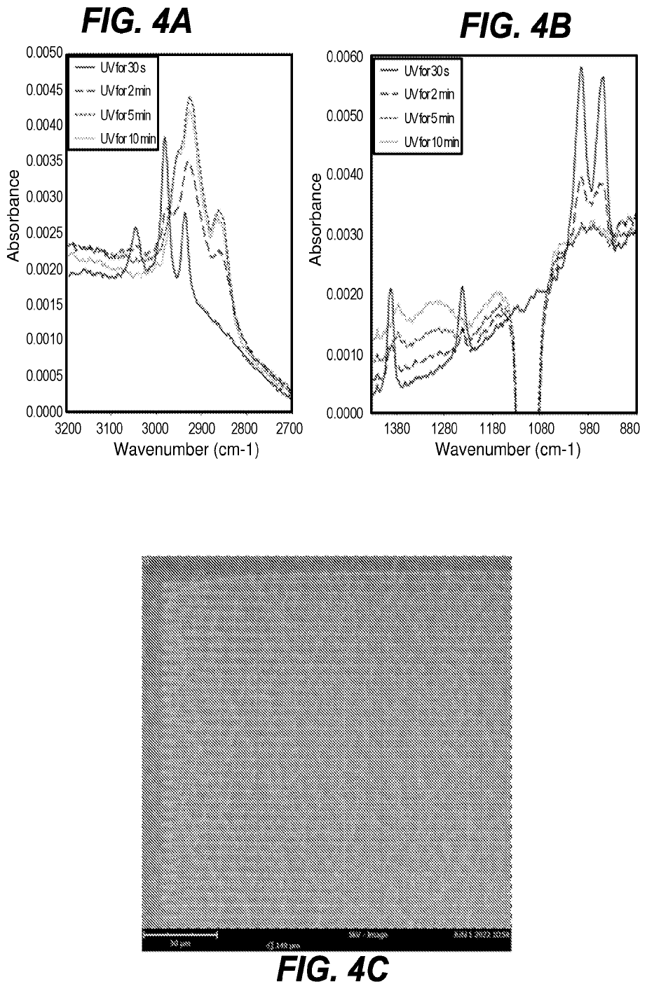

FIG. 4A is an FTIR spectrum of tin-oxo network formed from an alkenyl-substituent containing tin precursor and exposed to UV in accordance with certain disclosed embodiments. As shown in the spectrum, the UV treatment of a film formed from a vinyltri(t-butoxy)tin precursor and water caused a decrease in the intensity of the absorbance of ═C—H stretch peaks between 2900-3100 cm⁻¹ and new peaks attributed to saturated aliphatic —C—H stretches grow in between 2800-3000 cm⁻¹ increased in absorbance.

FIG. 4B represents another Fourier-transform infrared (FTIR) spectrum of tin-oxo network formed from an alkenyl-substituent containing tin precursor and exposed to UV in accordance with certain disclosed embodiments. In this spectrum, a decrease in absorbance of the vinylic bending modes at 1390 cm⁻¹, 1250 cm⁻¹, 995 cm⁻¹, and 950 cm⁻¹ was observed with UV treatment. Broad absorbance between 1150-1400 cm⁻¹ increased with UV treatment time. The changes observed in the IR spectrum upon UV treatment are consistent with a reaction mechanism where alkenyl substituents crosslink to a saturated alkyl network of carbon chains and bridges.

FIG. 4C is a scanning electron microscope (SEM) image of a tin-oxo network film formed from an alkenyl-substituent containing tin precursor after processing in accordance with certain disclosed embodiments. A film deposited from vinyltris(t-butoxy)tin and water film and exposed to a scanning electron beam in a SEM to mimic the effect of a EUV exposure followed by dry development with gas phase HBr. Dry development of the film was performed with a mixture of 500 sccm HBr co-flowed with 500 sccm Argon for 120s at 27° C. The chamber pressure was 1 Torr. The image shows a line pattern that is consistent with the electron beam scanning pattern. The line pattern could be imaged after dry development with HBr to remove areas of the film not exposed to the electron beam.

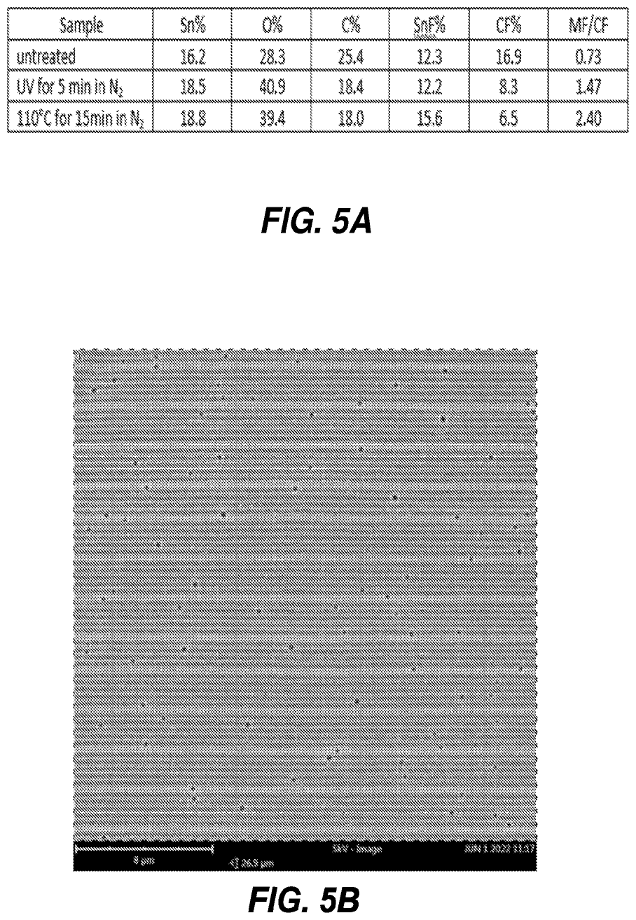

FIG. 5A is a table of x-ray photoelectron spectroscopy (XPS) data for a tin-oxo network film formed from a haloaliphatic-substituent containing tin precursor before and after processing in accordance with certain disclosed embodiments. XPS analysis of the tin-oxo network films before and after thermal treatment and exposure to UV (to mimic EUV). A tin fluoride (Sn—F bond) peak was observed 688.8 eV. The fluorine bonded to carbon (C—F bond) peak was observed at 685.6 eV. The ratio of MF/CF indicates the loss of fluorine bonded to carbon and the increase in fluorine bonded to tin.

FIG. 5B is a scanning electron microscope (SEM) image of a tin-oxo network film formed from a haloaliphatic-substituent containing tin precursor after processing in accordance with certain disclosed embodiments. The processing of the film included exposure to a scanning electron beam in a SEM followed by dry development with gas phase HBr. The film was baked at 110° C. for 2 minutes before dry development. Dry development of the film was performed with a mixture of 500 sccm HBr co-flowed with 500 sccm Ar for 120s at 27° C. The chamber pressure was 1 Torr.

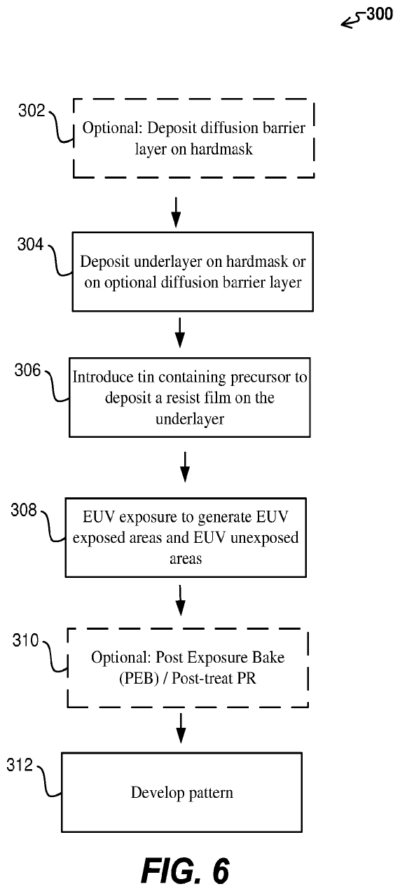

FIG. 6 is a flow diagram illustrating an embodiment of a process of the present invention. Process 300 for patterning of a hardmask includes deposition of an underlayer. Operation 302 is an optional initial deposition of a diffusion barrier on the hardmask. In operation 304, an underlayer is deposited directly on the hardmask, or on the diffusion barrier layer if it is present. A tin-containing precursor is utilized to deposit a resist film on the underlayer in operation 306. In operation 308 the resist film is exposed to extreme ultraviolet to generate EUV exposed areas and EUV unexposed areas. An optional post-exposure bake (PEB) takes place in operation 310. The pattern is then developed in operation 312.

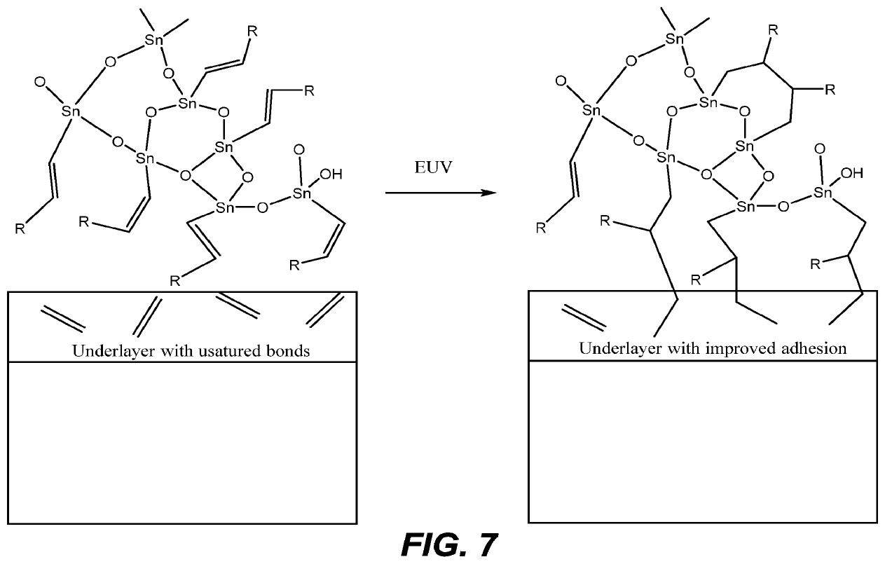

FIG. 7 is a schematic illustration of the structure of a tin-oxo network formed from an alkenyl-substituent containing tin precursor interacting with a carbon-based underlayer in the presence of EUV when the underlayer is a carbon-based based film. The carbon-based underlayer comprises a mixture of saturated and unsaturated bonds; and includes hydrogen, nitrogen, carbon and/or oxygen. A carbon-based film may contain unsaturated moieties which may interact with the alkenyl-substituents from the tin precursor to promote adhesion of the dry resist to the underlayer via hydrocarbon bridges in the EUV-exposed areas. These hydrocarbon bridges form a secondary hydrocarbon network which in some embodiments may increase etch resistance and/or reduce shrinkage.

The presence of this secondary hydrocarbon network is significant because the hydrocarbon and tin carbon bonds of the secondary hydrocarbon network do not react with HBr during dry development. The secondary hydrocarbon network blocks access of the HBr to the tin oxygen bonds in the metal-oxo network. In some embodiments, the secondary hydrocarbon network increases the molecular weight of etch byproducts, limiting removal of material from the EUV-exposed areas during dry development. The secondary hydrocarbon network thus assists with achievement of desired critical dimensions. Conventional films (lacking the secondary hydrocarbon network) may shrink from about 40% to about 60% during baking and/or during EUV exposure. In some embodiments, shrinkage takes place prior to dry development, and is measured after dry development occurs. In some embodiments, the secondary hydrocarbon network may increase etch resistance by up to 100% over films having a primary metal oxo-network alone. In some embodiments, the shrinkage of the resist film including a secondary hydrocarbon network may be 20% or even lower. In some embodiments, the shrinkage of films having a secondary hydrocarbon network may shrink from about 5 to about 55% less than resist films without one. In other embodiments, the shrinkage of films having a secondary hydrocarbon network will shrink from about 10 to about 40 percent less than resist films without one.

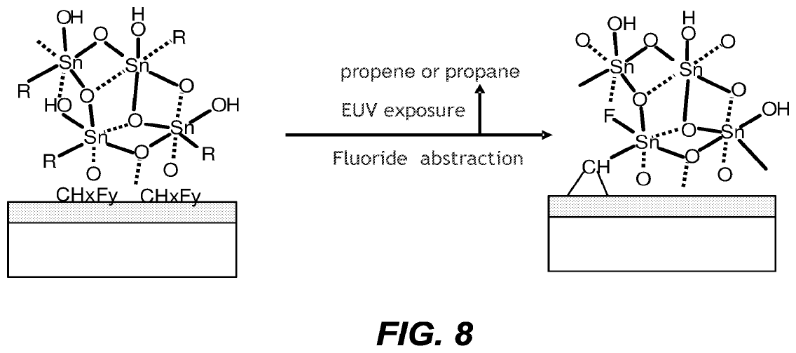

FIG. 8 is a schematic illustration of a tin-oxo network film formed from a haloaliphatic-substituent containing tin precursor interacting with a carbon-based underlayer in accordance with certain disclosed embodiments. Upon EUV exposure, a halide may be abstracted from the haloaliphatic substituent and may then bond directly to tin to form a stable, non-volatile tin-halide bonds. In some embodiments, the haloaliphatic substituent is a beta haloaliphatic substituent. For example, when the beta haloaliphatic substituent is —CH₂—CH₂—F, the fluorine may be abstracted while, before or after the ethylene bond to tin is broken. Subsequently the fluorine may bond directly to tin in the tin-oxo network, to form non-volatile Sn—F bonds, with concomitant release of ethylene gas.

As with the incorporation of C—F functionality into both tin precursors and active underlayers previously described, the concept of introducing cross-linkable substituents on the precursor is extendable to the underlayer interface. There are additional benefits and/or synergy associated with implementing both together, but potential advantages also extend to combinations withe precursors such as iso-propyl(tris)dimethylamino tin in some embodiments. Starting from the well-established baseline process flow for depositing amorphous/sp³ rich/diamond-like ashable hardmask (AHM) films from acetylene, conceptually the “least change” approach to films exhibiting high levels of conjugated sp² C═C bonding might involve termination steps following a steep decrease in temperature and plasma power and increase in acetylene. However, there exists a far wider overlap of process space and film stability for related composition generated from closely related methyl-substituted acetylenes such as propyne, 1-butyne and 2-butyne, phenyl- or trimethylsilylacetylene. Both the C—F doped and sp² double bond doped underlayer films seek to efficiently utilize the flux of secondary electrons generated at the bottom of the tin resist/underlayer interface to drive fluoride abstraction and involatile SnOₓF_{y} formation (in the former) and C—C and ultimately new Sn—C(underlayer) bond formation in the latter. Both mechanisms may, in some embodiments, amplify/enhance the formation of HBr etch resistant moieties at the bottom film interface counteracting the impact of EUV light depletion.

Due to the presence of the Sn—F bonds, etch resistance may be increased and/or shrinkage may be reduced.

### Apparatuses

The present disclosure also includes any apparatus configured to perform any methods described herein. In one embodiment, the apparatus for depositing a film includes a deposition module comprising a chamber for depositing an EUV-sensitive material as a film by providing a metal-containing precursor in the presence of an optional ligand-containing precursor; a patterning module comprising an EUV photolithography tool with a source of sub-30 nm wavelength radiation; and a development module comprising a chamber for developing the film.

The apparatus can further include a controller having instructions for such modules. In one embodiment, the controller includes one or more memory devices, one or more processors, and system control software coded with instructions for conducting deposition of the film or the capping layer. Such includes can include for, in the deposition module, depositing the resist film on a top surface of a substrate or a photoresist layer; in the patterning module, patterning the film with sub-30 nm resolution directly by EUV exposure, thereby forming a pattern within the film; and in the development module, developing the film. In particular embodiments, the development module provides for removal of the EUV exposed or EUV unexposed areas, thereby providing a pattern within the film.

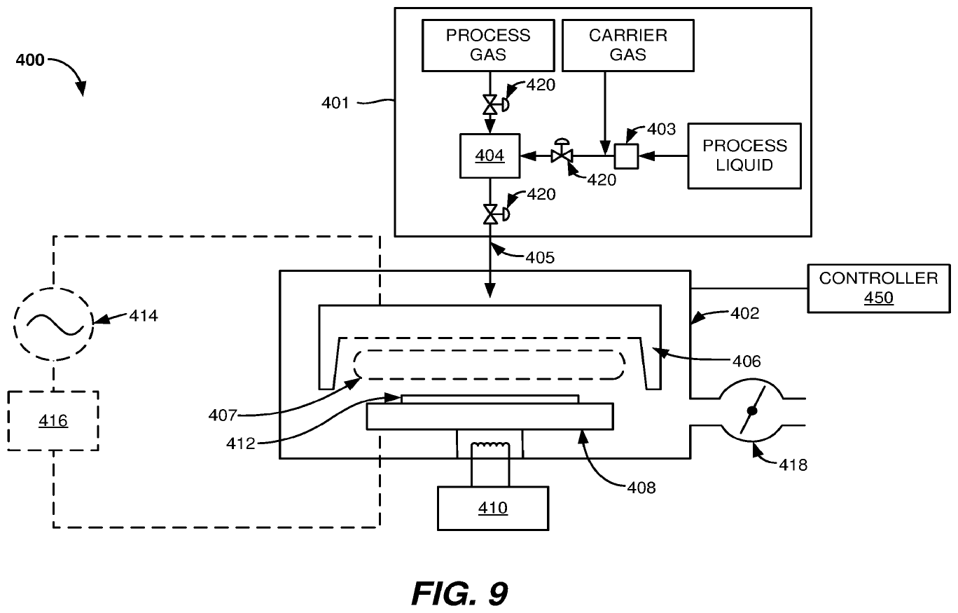

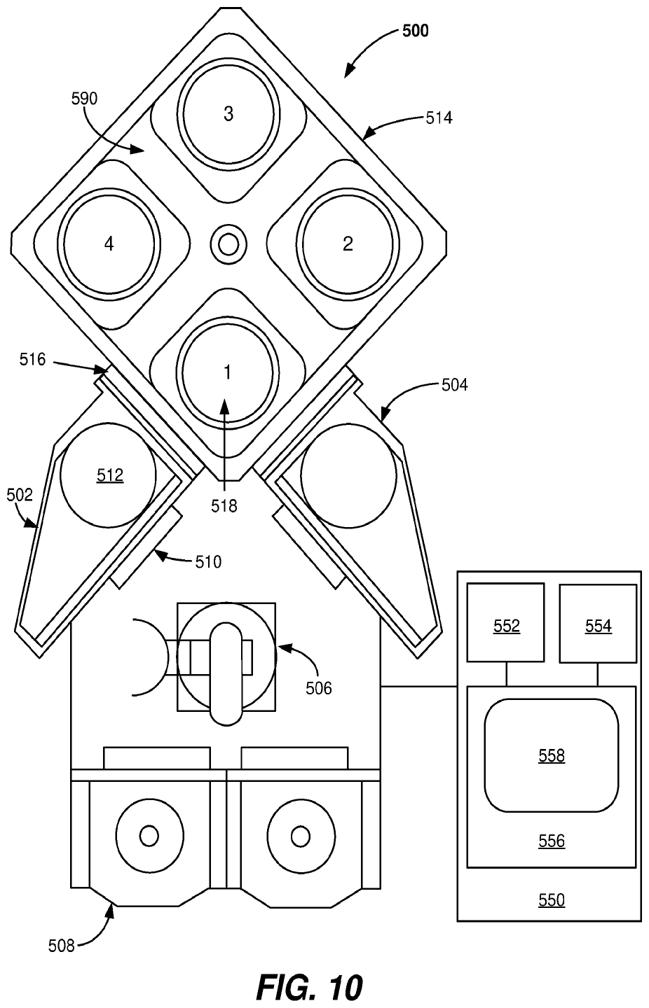

FIG. 9 depicts a schematic illustration of an embodiment of process station 400 having a process chamber body 402 for maintaining a low pressure environment that is suitable for implementation of described dry stripping and development embodiments. A plurality of process stations 400 may be included in a common low pressure process tool environment. For example, FIG. 10 depicts an embodiment of a multi-station processing tool 500, such as a VECTOR® processing tool available from Lam Research Corporation, Fremont, CA. In some embodiments, one or more hardware parameters of the process station 400 including those discussed in detail below may be adjusted programmatically by one or more computer controllers 450.

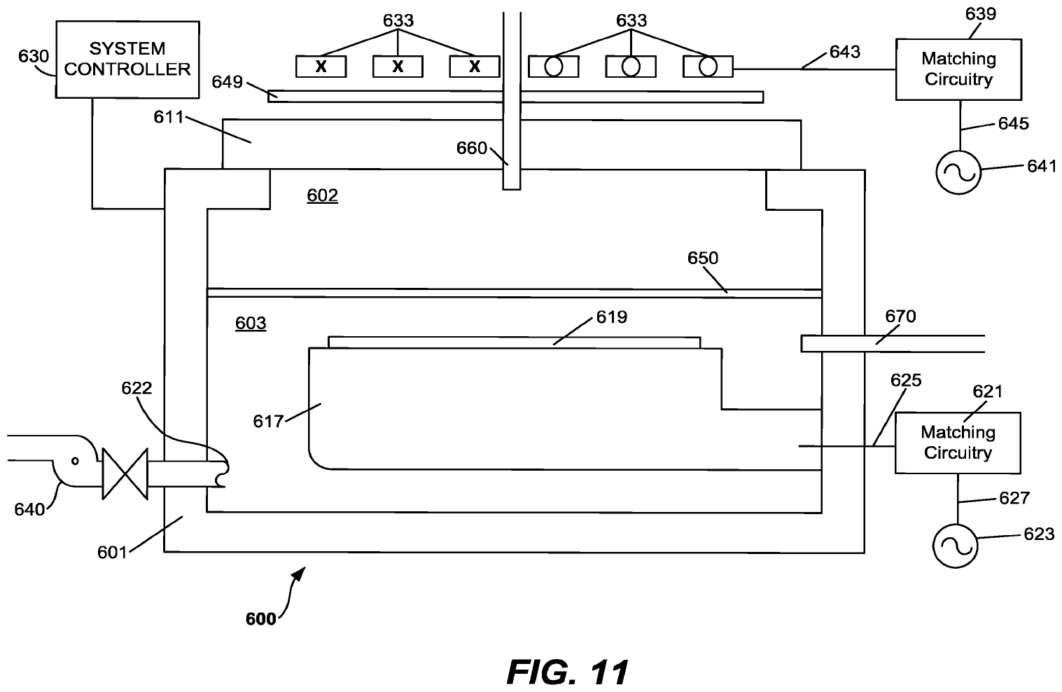

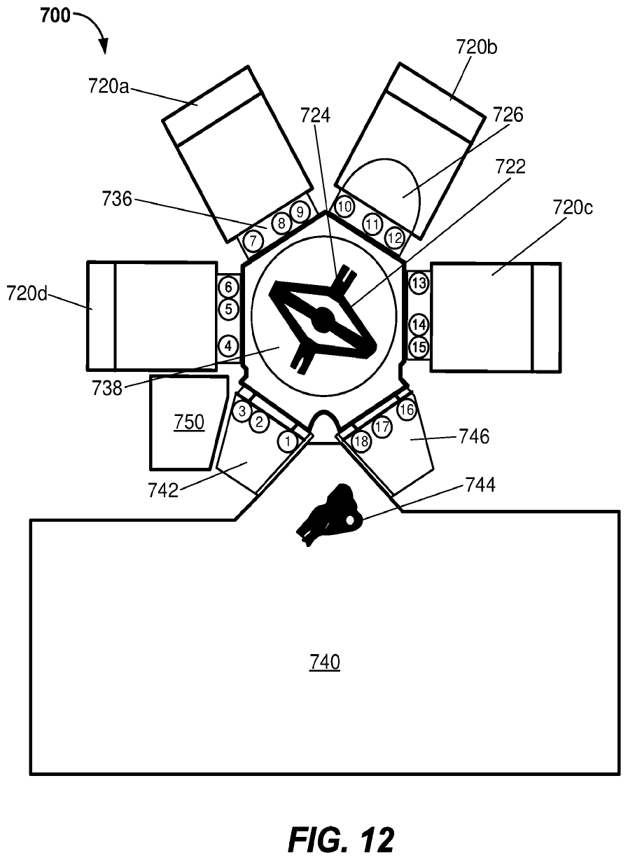

A process station may be configured as a module in a cluster tool. FIG. 12 depicts a semiconductor process cluster tool architecture with vacuum-integrated deposition and patterning modules suitable for implementation of the embodiments described herein. Such a cluster process tool architecture can include resist deposition, resist exposure (EUV scanner), resist dry development and etch modules, as described herein with reference to FIG. 11 and FIG. 12.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 9, process station 400 fluidly communicates with reactant delivery system 401 for delivering process gases to a distribution showerhead 406 by a connection 405. Reactant delivery system 401 optionally includes a mixing vessel 404 for blending and/or conditioning process gases, for delivery to showerhead 406. One or more mixing vessel inlet valves 420 may control introduction of process gases to mixing vessel 404. Where plasma exposure is used, plasma may also be delivered to the showerhead 406 or may be generated in the process station 400. Process gases can include, e.g., any described herein, such as a metal-containing precursor, a ligand-containing precursor, or a counter-reactant.

FIG. 9 includes an optional vaporization point 403 for vaporizing liquid reactant to be supplied to the mixing vessel 404. The liquid reactant can include a metal-containing precursor, a ligand-containing precursor, or a counter-reactant. In some embodiments, a liquid flow controller (LFC) upstream of vaporization point 403 may be provided for controlling a mass flow of liquid for vaporization and delivery to process station 400. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 406 distributes process gases toward substrate 412. In the embodiment shown in FIG. 9, the substrate 412 is located beneath showerhead 406 and is shown resting on a pedestal 408. Showerhead 406 may have any suitable shape and may have any suitable number and arrangement of ports for distributing process gases to substrate 412.

In some embodiments, pedestal 408 may be raised or lowered to expose substrate 412 to a volume 407 between the substrate 412 and the showerhead 406. It will be appreciated that, in some embodiments, pedestal height may be adjusted programmatically by a suitable computer controller 450.

In some embodiments, pedestal 408 may be temperature controlled via heater 410. In some embodiments, the pedestal 408 may be heated to a temperature of greater than 0° C. and up to 300° C. or more, for example 50-120° C., such as about 65-80° C., during non-plasma thermal exposure of a photopatterned resist to dry development chemistry, such as HBr, HCl, or BCl₃, as described in disclosed embodiments.

Further, in some embodiments, pressure control for process station 400 may be provided by a butterfly valve 418. As shown in the embodiment of FIG. 9, butterfly valve 418 throttles a vacuum provided by a downstream vacuum pump (not shown). However, in some embodiments, pressure control of process station 400 may also be adjusted by varying a flow rate of one or more gases introduced to the process station 400.

In some embodiments, a position of showerhead 406 may be adjusted relative to pedestal 408 to vary a volume 407 between the substrate 412 and the showerhead 406. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers 450.

Where plasma may be used, for example in gentle plasma-based dry development embodiments and/or etch operations conducted in the same chamber, showerhead 406 and pedestal 408 electrically communicate with a radio frequency (RF) power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are up to about 500 W.

In some embodiments, instructions for a controller 450 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 450 may include any of the features described below with respect to system controller 550 of FIG. 10.

As described above, one or more process stations may be included in a multi station processing tool. FIG. 10 shows a schematic view of an embodiment of a multi station processing tool 500 with an inbound load lock 502 and an outbound load lock 504, either or both of which may include a remote plasma source. A robot 506 at atmospheric pressure is configured to move wafers from a cassette loaded through a pod 508 into inbound load lock 502 via an atmospheric port 510. A wafer is placed by the robot 506 on a pedestal 512 in the inbound load lock 502, the atmospheric port 510 is closed, and the load lock is pumped down. Where the inbound load lock 502 includes a remote plasma source, the wafer may be exposed to a remote plasma treatment to treat the silicon nitride surface in the load lock prior to being introduced into a processing chamber 514. Further, the wafer also may be heated in the inbound load lock 502 as well, for example, to remove moisture and adsorbed gases. Next, a chamber transport port 516 to processing chamber 514 is opened, and another robot (not shown) places the wafer into the reactor on a pedestal of a first station shown in the reactor for processing. While the embodiment depicted in FIG. 10 includes load locks, it will be appreciated that, in some embodiments, direct entry of a wafer into a process station may be provided.

The depicted processing chamber 514 includes four process stations, numbered from 1 to 4 in the embodiment shown in FIG. 10. Each station has a heated pedestal (shown at 518 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 514 may include one or more matched pairs of dry development and etch process stations. While the depicted processing chamber 514 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 10 depicts an embodiment of a wafer handling system 590 for transferring wafers within processing chamber 514. In some embodiments, wafer handling system 590 may transfer wafers between various process stations and/or between a process station and a load lock. It will be appreciated that any suitable wafer handling system may be employed. Non limiting examples include wafer carousels and wafer handling robots. FIG. 10 also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog, and/or digital input/output connections, stepper motor controller boards, etc.

In some embodiments, system controller 550 controls all of the activities of process tool 500. System controller 550 executes system control software 558 stored in mass storage device 554, loaded into memory device 556, and executed on processor 552. Alternatively, the control logic may be hard coded in the controller 550. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 558 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 500. System control software 558 may be configured in any suitable way. For example, various process tool component subroutines or control objects may be written to control operation of the process tool components used to carry out various process tool processes. System control software 558 may be coded in any suitable computer readable programming language.

In some embodiments, system control software 558 may include input/output control (IOC) sequencing instructions for controlling the various parameters described above. Other computer software and/or programs stored on mass storage device 554 and/or memory device 556 associated with system controller 550 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 518 and to control the spacing between the substrate and other parts of process tool 500.

A process gas control program may include code for controlling various gas compositions (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 550 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 550 from various process tool sensors. The signals for controlling the process may be output on the analog and digital output connections of process tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 550 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 550 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 550.

In some implementations, the system controller 550 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 550, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 550 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 550 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 550, in some implementations, may be a part of or coupled to a computer that is integrated with, coupled to the system, otherwise networked to the system, or a combination thereof. For example, the system controller 550 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 550 receives instructions in the form of data, which specify parameters for each of the processing steps to be performed during one or more operations. It should be understood that the parameters may be specific to the type of process to be performed and the type of tool that the system controller 550 is configured to interface with or control. Thus, as described above, the system controller 550 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 550 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 11 schematically shows a cross-sectional view of an inductively coupled plasma apparatus 600 appropriate for implementing certain embodiments or aspects of embodiments such as dry development and/or etch, an example of which is a Kiyo® reactor, produced by Lam Research Corp. of Fremont, CA. In other embodiments, other tools or tool types having the functionality to conduct the dry development and/or etch processes described herein may be used for implementation.

The inductively coupled plasma apparatus 600 includes an overall process chamber structurally defined by chamber walls 601 and a window 611. The chamber walls 601 may be fabricated from stainless steel or aluminum. The window 611 may be fabricated from quartz or other dielectric material. An optional internal plasma grid 650 divides the overall process chamber into an upper sub-chamber 602 and a lower sub-chamber 603. In most embodiments, plasma grid 650 may be removed, thereby utilizing a chamber space made of sub-chambers 602 and 603. A chuck 617 is positioned within the lower sub-chamber 603 near the bottom inner surface. The chuck 617 is configured to receive and hold a semiconductor wafer 619 upon which the etching and deposition processes are performed. The chuck 617 can be an electrostatic chuck for supporting the wafer 619 when present. In some embodiments, an edge ring (not shown) surrounds the chuck 617 and has an upper surface that is approximately planar with a top surface of the wafer 619, when present over the chuck 617. The chuck 617 also includes electrostatic electrodes for chucking and dechucking the wafer 619. A filter and DC clamp power supply (not shown) may be provided for this purpose.

Other control systems for lifting the wafer 619 off the chuck 617 can also be provided. The chuck 617 can be electrically charged using an RF power supply 623. The RF power supply 623 is connected to matching circuitry 621 through a connection 627. The matching circuitry 621 is connected to the chuck 617 through a connection 625. In this manner, the RF power supply 623 is connected to the chuck 617. In various embodiments, a bias power of the electrostatic chuck may be set at about 50 V or may be set at a different bias power depending on the process performed in accordance with disclosed embodiments. For example, the bias power may be between about 20 V and about 100 V, or between about 30 V and about 150 V.

Elements for plasma generation include a coil 633 positioned above window 611. In some embodiments, a coil is not used in disclosed embodiments. The coil 633 is fabricated from an electrically conductive material and includes at least one complete turn. The example of a coil 633 shown in FIG. 11 includes three turns. The cross sections of coil 633 are shown with symbols, and coils having an “X” extend rotationally into the page, while coils having a “⋅” extend rotationally out of the page. Elements for plasma generation also include an RF power supply 641 configured to supply RF power to the coil 633. In general, the RF power supply 641 is connected to matching circuitry 639 through a connection 645. The matching circuitry 639 is connected to the coil 633 through a connection 643. In this manner, the RF power supply 641 is connected to the coil 633. An optional Faraday shield 649 is positioned between the coil 633 and the window 611. The Faraday shield 649 may be maintained in a spaced apart relationship relative to the coil 633. In some embodiments, the Faraday shield 649 is disposed immediately above the window 611. In some embodiments, a Faraday shield is between the window 611 and the chuck 617. In some embodiments, the Faraday shield is not maintained in a spaced apart relationship relative to the coil 633. For example, a Faraday shield may be directly below the window without a gap. The coil 633, the Faraday shield 649, and the window 611 are each configured to be substantially parallel to one another. The Faraday shield 649 may prevent metal or other species from depositing on the window 611 of the process chamber.

Process gases may be flowed into the process chamber through one or more main gas flow inlets 660 positioned in the upper sub-chamber 602 and/or through one or more side gas flow inlets 670. Likewise, though not explicitly shown, similar gas flow inlets may be used to supply process gases to a capacitively coupled plasma processing chamber. A vacuum pump, e.g., a one or two stage mechanical dry pump and/or turbomolecular pump 640, may be used to draw process gases out of the process chamber and to maintain a pressure within the process chamber. For example, the vacuum pump may be used to evacuate the lower sub-chamber 603 during a purge operation of ALD. A valve-controlled conduit may be used to fluidically connect the vacuum pump to the process chamber so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 600, one or more process gases may be supplied through the gas flow inlets 660 and/or 670. In certain embodiments, process gas may be supplied only through the main gas flow inlet 660, or only through the side gas flow inlet 670. In some cases, the gas flow inlets shown in the figure may be replaced by more complex gas flow inlets, one or more showerheads, for example. The Faraday shield 649 and/or optional grid 650 may include internal channels and holes that allow delivery of process gases to the process chamber. Either or both of Faraday shield 649 and optional grid 650 may serve as a showerhead for delivery of process gases. In some embodiments, a liquid vaporization and delivery system may be situated upstream of the process chamber, such that once a liquid reactant or precursor is vaporized, the vaporized reactant or precursor is introduced into the process chamber via a gas flow inlet 660 and/or 670.

Radio frequency power is supplied from the RF power supply 641 to the coil 633 to cause an RF current to flow through the coil 633. The RF current flowing through the coil 633 generates an electromagnetic field about the coil 633. The electromagnetic field generates an inductive current within the upper sub-chamber 602. The physical and chemical interactions of various generated ions and radicals with the wafer 619 etch features of and selectively deposit layers on the wafer 619.

If the plasma grid 650 is used such that there is both an upper sub-chamber 602 and a lower sub-chamber 603, the inductive current acts on the gas present in the upper sub-chamber 602 to generate an electron-ion plasma in the upper sub-chamber 602. The optional internal plasma grid 650 limits the amount of hot electrons in the lower sub-chamber 603. In some embodiments, the apparatus 600 is designed and operated such that the plasma present in the lower sub-chamber 603 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 603 through port 622. The chuck 617 disclosed herein may operate at elevated temperatures ranging between about 10-250° C. The temperature will depend on the process operation and specific recipe.

Apparatus 600 may be coupled to facilities (not shown) when installed in a clean room or a fabrication facility. Facilities include plumbing that provide processing gases, vacuum, temperature control, and environmental particle control. These facilities are coupled to apparatus 600, when installed in the target fabrication facility. Additionally, apparatus 600 may be coupled to a transfer chamber that allows robotics to transfer semiconductor wafers into and out of apparatus 600 using typical automation.

In some embodiments, a system controller 630 (which may include one or more physical or logical controllers) controls some or all of the operations of a process chamber. The system controller 630 may include one or more memory devices and one or more processors. In some embodiments, the apparatus 600 includes a switching system for controlling flow rates and durations when disclosed embodiments are performed. In some embodiments, the apparatus 600 may have a switching time of up to about 600 ms, or up to about 750 ms. Switching time may depend on the flow chemistry, recipe chosen, reactor architecture, and other factors.

In some implementations, the system controller 630 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 630, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 630 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 630, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 630 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 630 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL. The EUVL patterning tool may be a standalone device from which the substrate is moved into and out of for deposition and etching as described herein. Or, as described below, the EUVL patterning tool may be a module on a larger multi-component tool. FIG. 12 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 12 depicts a semiconductor process cluster tool architecture 700 with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 738 interfaces with four processing modules 720a-720d, which may be individually optimized to perform various fabrication processes. By way of example, processing modules 720a-720d may be implemented to perform deposition, evaporation, ELD, dry development, etch, strip, and/or other semiconductor processes. For example, module 720a may be an ALD reactor that may be operated to perform in a non-plasma, thermal atomic layer depositions as described herein, such as a Vector tool, available from Lam Research Corporation, Fremont, CA. And module 720b may be a PECVD tool, such as the Lam Vector®. It should be understood that the figure is not necessarily drawn to scale.

Airlocks 742 and 746, also known as a loadlocks or transfer modules, interface with the VTM 738 and a patterning module 740. For example, as noted above, a suitable patterning module may be the TWINSCAN NXE: 3300B® platform supplied by ASML of Veldhoven, NL. This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 12 but without the integrated patterning module.

Airlock 742 may be an “outgoing” loadlock, referring to the transfer of a substrate out from the VTM 738 serving a deposition module 720a to the patterning module 740, and airlock 746 may be an “ingoing” loadlock, referring to the transfer of a substrate from the patterning module 740 back in to the VTM 738. The ingoing loadlock 746 may also provide an interface to the exterior of the tool for access and egress of substrates. Each process module has a facet that interfaces the module to VTM 738. For example, deposition process module 720a has facet 736. Inside each facet, sensors, for example, sensors 1-18 as shown, are used to detect the passing of wafer 726 when moved between respective stations. Patterning module 740 and airlocks 742 and 746 may be similarly equipped with additional facets and sensors, not shown.

Main VTM robot 722 transfers wafer 726 between modules, including airlocks 742 and 746. In one embodiment, robot 722 has one arm, and in another embodiment, robot 722 has two arms, where each arm has an end effector 724 to pick wafers such as wafer 726 for transport. Front-end robot 744, in is used to transfer wafers 726 from outgoing airlock 742 into the patterning module 740, from the patterning module 740 into ingoing airlock 746. Front-end robot 744 may also transport wafers 726 between the ingoing loadlock and the exterior of the tool for access and egress of substrates. Because ingoing airlock module 746 has the ability to match the environment between atmospheric and vacuum, the wafer 726 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 742 may provide this function by holding the transferred wafers at a lower pressure, no higher than the pressure in the patterning module 740, for a period of time and exhausting any off-gassing, so that the optics of the patterning tool 740 are not contaminated by off-gassing from the substrate. A suitable pressure for the outgoing, off-gassing airlock is no more than 1E-8 Torr.

In some embodiments, a system controller 750 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 750 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A precursor composition for forming an irradiation-sensitive resist film, comprising:
a precursor of the formula M(R¹)₄, wherein M is a metal selected from the group consisting of lead, germanium, tin, and hafnium, each R¹ is independently aliphatic, alkylsilyl, amino, amido, azido, cyano, alkylcarbonyl, isocyanato, isothiocyanato, thiocyanato, alkoxy, heterocyclyl, aryl, alkenyl or alkynyl, or R¹ substituents may be linked to form a ring and wherein at least one R¹ is an unsaturated substituent;
wherein the precursor forms a primary metal-oxo network film having unsaturated substituents after deposition on a substrate; and
wherein the unsaturated substituents in the primary metal-oxo network film form a secondary hydrocarbon network upon exposure to radiation with the proviso that when M is tin and each R¹ is the same, R¹ is alkynyl.

2. The precursor composition of claim 1, wherein the secondary hydrocarbon network increases etch resistance.

3. The precursor composition of claim 1, wherein the secondary hydrocarbon network reduces film shrinkage after patterning.

4. The precursor composition of claim 1, wherein M is tin and wherein the composition comprises less than 0.5% of a tin-containing compound comprising two aliphatic R¹ substituents.

5. A method of processing a semiconductor substrate comprising:
depositing a precursor of the formula M(R¹)₄, wherein M is a metal selected from the group consisting of lead, germanium, tin and hafnium, and each R¹ is independently aliphatic, alkylsilyl, amino, amido, azido, cyano, alkylcarbonyl, isocyanato, isothiocyanato, thiocyanato, alkoxy, heterocyclyl, aryl, alkenyl or alkynyl, or R¹ substituents may be linked to form a ring and wherein at least one R¹ is an unsaturated substituent, with the proviso that when M is tin and each R¹ is the same, R¹ is alkynyl, on a substrate to form an irradiation sensitive metal-oxo network resist film; and
patterning the metal-oxo network resist film having unsaturated substituents by extreme ultraviolet exposure to form a photopatterned metal-oxo network resist film;
wherein unsaturated substituents in the metal-oxo network resist film form a secondary hydrocarbon network upon exposure to radiation to form a photopatterned and cross-linked metal-oxo network resist film.

6. The method of claim 5, further comprising dry developing the photopatterned and cross-linked metal-oxo network resist film to form a resist mask.

7. The method of claim 5, wherein the secondary hydrocarbon network increases etch resistance.

8. The method of claim 5, wherein the secondary hydrocarbon network reduces film shrinkage after patterning.

9. The method of claim 5, wherein the metal is tin.

10. The method of claim 9, wherein the precursor comprises a structure of formula 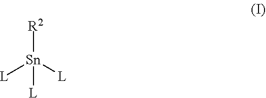
wherein R² is C₂₋₆ aliphatic; and
each L is independently NR³R⁴ or OR⁵, wherein R³, R⁴ and R⁵ are each independently hydrogen, alkylcarbonyl or aliphatic, and wherein R³ and R⁴ substituents may be linked to form a ring.

11. The method of claim 10, wherein each L is NR³R⁴.

12. The method of claim 11, wherein L is dimethylamino, tert-butylamino, diethylamino, ethylmethylamino, methylpropylamino, pyrrolidino or piperidino.

13. The method of claim 10, wherein each L is OR⁵.

14. The method of claim 13, wherein L is methoxy, ethoxy, n-propoxy, iso-propoxy, tert-butoxy, sec-butoxy or n-butoxy.

15. The method of claim 5, wherein the unsaturated substituent is C₂-C₆ alkenyl, C₂-C₆ branched alkenyl or C₂-C₆ alkynyl.

16. The method of claim 5, wherein the unsaturated substituent is C₅-C₆ alkenyl, C₅-C₆ branched alkenyl or C₅-C₆ alkynyl.

17. The method of claim 9, wherein the precursor is vinyl tri(methoxy)tin, vinyl tri(ethoxy)tin, vinyl tri(iso-propoxy)tin, vinyl tri(tert-butoxy) tin, vinyltris(dimethylamino)tin, vinyl tris(pyrrolidino)tin, 2-propenyl tri(iso-propoxy)tin, 2-propenyl tri(tert-butoxy)tin, 2-propenyl tris(dimethylamino)tin, 2-propenyl tris(pyrrolidino)tin, 2-methyl-1-propenyl tri(iso-propoxy)tin, 2-methyl-1-propenyl tri(tert-butoxy)tin, 2-methyl-1-propenyl tris(dimethylamino)tin, 2-propenyl tris(pyrrolidino)tin, vinyl tri(1-propynyl)tin, isopropenyl tri(1-propynyl)tin, isopropenyl tris(dimethylamino)tin, 2-methyl-1-propenyl tri(1-propynyl)tin, allyl tri(iso-propoxy)tin, allyl tri(tertbutoxy)tin, allyl tris(dimethylamino)tin, allyl tris(pyrrolidino)tin, allyl tri(1-propynyl)tin, 1-methylallyl tri(iso-propoxy)tin, 1-methylallyl tri(tert-butoxy)tin, 1-methylallyl tris(dimethylamino)tin, 1-methylallyl tris(pyrrolidino)tin or 1-methylallyl tri(1-propynyl)tin.

18. A precursor composition for forming an irradiation-sensitive resist film, comprising:
a precursor of the formula M(R⁶)₄, wherein M is a metal selected from the group consisting of lead, germanium, tin, and hafnium; and
each R⁶ is independently aliphatic, alkylsilyl, amino, amido, azido, cyano, alkylcarbonyl, isocyanato, isothiocyanato, thiocyanato, alkoxy, heterocyclyl, haloaliphatic, aryl or R⁶ substituents may be linked to form a ring, and wherein at least one R⁶ is a halo-containing substituent; and
wherein the precursor forms a metal-oxo network resist film having halo-containing substituents and the halo-containing substituents form metal-halo bonds upon exposure to radiation.

19. A method of processing a semiconductor substrate comprising:
depositing a precursor of the formula M(R⁶)₄, wherein M is a metal selected from the group consisting of lead, germanium, tin and hafnium, and each R⁶ is independently aliphatic, alkylsilyl, amino, amido, azido, cyano, alkylcarbonyl, isothiocyanato, thiocyanato, alkoxy, heterocyclyl, haloaliphatic, aryl or R⁶ substituents may be linked to form a ring, and wherein at least one R⁶ is a halo-containing substituent, on a substrate to form an irradiation sensitive metal-oxo network resist film having halo-containing substituents; and
patterning the irradiation sensitive metal-oxo network resist film having halo containing substituents by extreme ultraviolet exposure to form a photopatterned and metal-halo bond containing metal oxo network resist film.

20. The method of claim 19, further comprising dry developing the photopatterned and metal-halo bond containing metal-oxo network resist film to form a resist mask.

21. The method of claim 19, wherein the metal is tin.

22. The method of claim 19, wherein the halo-containing substituent is a beta halo containing substituent.

23. The method of claim 21, wherein the precursor comprises a structure of formula (II): 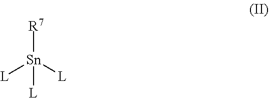
wherein R⁷ is C₂₋₆ haloaliphatic; and
each L is independently NR⁸R⁹ or OR¹⁰, wherein R⁸, R⁹ and R¹⁰ are each independently hydrogen, alkylcarbonyl or aliphatic, and wherein R⁸ and R⁹ substituents may be linked to form a ring.

24. The method of claim 23, wherein each L is NR⁸R⁹.

25. The method of claim 24, wherein L is dimethylamino, tert-butylamino, diethylamino, ethylmethylamino, methylpropylamino, pyrrolidino or piperidino.

26. A patterning radiation-sensitive film comprising an organometal-oxo material, wherein the material comprises:
a metal, oxygen, and an alkylsilyl, heterocyclyl or aryl.

27. The film of claim 26, wherein the alkylsilyl is trimethylsilyl, triethylsilyl, tert-butyldimethylsilyl, ethyldimethylsilyl or tri-isopropylsilyl.

28. The film of claim 26, wherein the aryl is phenyl, benzyl or methylcyclopentadienyl.

29. The film of claim 26, wherein the heterocyclyl is imidazolyl, pyrrolidinyl, pyridinyl, tetrahydrofuranyl, tetrahydropyranyl or dioxanyl.

30. The film of claim 26, wherein the organo-metal oxo material comprises a network of metal-oxygen bonds and metal-alkylsilyl or metal-heterocyclyl bonds.

31. The film of claim 26, wherein the patterning radiation-sensitive film comprises an extreme ultraviolet-sensitive film.

32. The film of claim 26, wherein the metal is tin.

33. A patterning radiation-sensitive film comprising an organotin-oxo material, wherein an orgaontin-oxo material comprises:
tin, oxygen, and a C₅₋₆ aliphatic or C₅₋₆ haloaliphatic.

34. The film of claim 33, wherein the C₅₋₆ haloaliphatic is C₅₋₆ haloalkyl, C₅₋₆ haloalkenyl or C₅₋₆ haloalkynyl.

35. The film of claim 34, wherein the C₅₋₆ haloaliphatic comprises one or more halo substitutions.

36. The film of claim 33, wherein the C₅₋₆ aliphatic is pentyl, pentenyl, pentynyl, hexyl, hexenyl or hexynyl.

37. The film of claim 33, wherein the C₅₋₆ aliphatic is cyclopentyl, cyclohexyl, cyclopentenyl, cyclohexenyl or cyclohexadienyl.

38. The film of claim 33, wherein the material comprises a network of tin-oxygen bonds and tin-C₅₋₆ aliphatic or tin-C₅₋₆ haloaliphatic bonds.
